(19) United States
(12) Patent Application Publication
(10) Pub. No.: US 2026/0371903 A1
(43) Pub. Date: Nov. 19, 2026

(54) DISPLAY DEVICE AND ELECTRONIC DEVICE INCLUDING THE SAME

(71) Applicant: SAMSUNG DISPLAY CO., LTD., YONGIN-SI (KR)

(72) Inventors: Seung Lyong BOK, Yongin-si (KR); Hae Ju YUN, Yongin-si (KR)

(21) Appl. No.: 19/396,823

(22) Filed: Nov. 21, 2025

(30) Foreign Application Priority Data
Mar. 27, 2025 (KR) 10-2025-0039266

(51) Int. Cl. H10K 59/80; G02F 1/167; H10K 59/50; H10K 102/00

(52) U.S. Cl. CPC H10K 59/878; G02F 1/167; H10K 59/50; H10K 2102/311

(57) ABSTRACT

A display device includes a first non-folding display area including a first display area, a second non-folding display area including a second display area and connected to a side of the first non-folding display area, a third non-folding display area including a third display area and connected to a side of the second non-folding display area, a fourth non-folding display area including a fourth display area and connected to a side of the third non-folding display area, a first folding display area bendable located between the first non-folding display area and the second non-folding display area, a second folding display area bendable located between the second non-folding display area and the third non-folding display area, and a third folding display area bendable located between the third non-folding display area and the fourth non-folding display area.

This application claims priority under 35 U.S.C. § 119 to Korean Patent Application No. 10-2025-0039266, filed on Mar. 27, 2025 in the Korean Intellectual Property Office, the present disclosure of which is incorporated by reference in its entirety herein.

### 1. TECHNICAL FIELD

The present disclosure relates to a display device and an electronic device including the same.

### 2. DISCUSSION OF RELATED ART

An increasing variety of display devices have been developed to display information along with the advancement of the information society. For example, a transparent display device allows a viewer to see the background through the display device. As another example, a 3D display shows three-dimensional images to give a viewer a sense of visual depth.

Transparent displays should have a high transparency so that a viewer can clearly see objects located on the back of the display. 3D displays should provide images at various points of view to provide 3D experiences to users. With the emergence of various display devices, research is being conducted to provide more compelling user experiences.

### SUMMARY

Aspects of the present disclosure provide a display device that displays a plurality of parallax images to the user.

Aspects of the present disclosure also provide an electronic device including a display device that displays a plurality of parallax images to the user.

According to an embodiment of the present disclosure, a display device include a first non-folding display area including a first display area, a second non-folding display area including a second display area and connected to a side of the first non-folding display area, a third non-folding display area including a third display area and connected to a side of the second non-folding display area, a fourth non-folding display area including a fourth display area and connected to a side of the third non-folding display area, a first folding display area located between the first non-folding display area and the second non-folding display area and being bendable, a second folding display area located between the second non-folding display area and the third non-folding display area and being bendable, and a third folding display area located between the third non-folding display area and the fourth non-folding display area and being bendable. The display device operates in one of a first mode or a second mode, wherein the first non-folding display area to the fourth non-folding display area are arranged on a same plane as each other in the first mode and the first non-folding display area to the fourth non-folding display area are arranged on different planes from each other in the second mode. The fourth non-folding display area may include a variably transparent layer that reflects or transmits a portion of light incident from outside depending on incidence surfaces.

According to an embodiment of the present disclosure, the fourth non-folding display area may further include a variably transparent area located around the fourth display area. The variably transparent layer may be located in the variably transparent area.

According to an embodiment of the present disclosure, the variably transparent layer may include a metal layer having a thickness less than or equal to about 50 nm.

According to an embodiment of the present disclosure, the fourth non-folding display area may further include a reflective area located around the fourth display area, and a transmissive area located around the fourth display area and the reflective area. The variably transparent layer may be located in the reflective area.

According to an embodiment of the present disclosure, the variably transparent layer may include cholesteric liquid crystal.

According to an embodiment of the present disclosure, the variably transparent layer may include an electrophoretic display.

According to an embodiment of the present disclosure, the third non-folding display area may further include a transparent area surrounding the third display area.

According to an embodiment of the present disclosure, the variably transparent layer may reflect light displayed in the second non-folding display area in the second mode.

According to an embodiment of the present disclosure, the variably transparent layer may transmit light displayed in the first non-folding display area in the second mode.

According to an embodiment of the present disclosure, the third non-folding display area may transmit light displayed in the fourth non-folding display area in the second mode.

According to an embodiment of the present disclosure, light from the first display area may be recognized as being adjacent to the second display area and the third display area in the second mode. Light from the fourth display area may be recognized as being adjacent to the second display area and the third display area in the second mode.

According to an embodiment of the present disclosure, the third non-folding display area and the fourth non-folding display area may be transparent displays.

According to an embodiment of the present disclosure, the display device may further include a housing in having the first to fourth non-folding display areas and the first to third folding display areas arranged therein. The housing may include a first non-folding housing portion located on a side of the first non-folding display area, a second non-folding housing portion located on a side of the second non-folding display area, a third non-folding housing portion located on some of edges of the third non-folding display area, a fourth non-folding housing portion located on some of edges of the fourth non-folding display area, a first folding housing portion located between the first non-folding housing portion and the second non-folding housing portion, a second folding housing portion located between the second non-folding housing portion and the third non-folding housing portion, and a third folding housing portion located between the third non-folding housing portion and the fourth non-folding housing portion.

According to an embodiment of the present disclosure, the display device may further include a housing having the first to fourth non-folding display areas and the first to third folding display areas arranged therein. The housing may include a first non-folding housing portion located on some of edges of the first non-folding display area, a second non-folding housing portion located on a surface of the second non-folding display area, a third non-folding housing portion located on some of edges of the third non-folding display area, a fourth non-folding housing portion located on some of edges of the fourth non-folding display area, a first folding housing portion located between the first non-folding housing portion and the second non-folding housing portion, a second folding housing portion located between the second non-folding housing portion and the third non-folding housing portion, and a third folding housing portion located between the third non-folding housing portion and the fourth non-folding housing portion.

According to an embodiment of the present disclosure, the display device includes a display panel. The display panel includes a substrate, a plurality of light-emitting elements arranged on the substrate, and arranged in light-emitting areas of the first non-folding display area to the fourth non-folding display area and the first folding display area to the third folding display area, and an encapsulation layer located on the plurality of light-emitting elements.

According to an embodiment of the present disclosure, the display panel may further include a plurality of inorganic insulating layers arranged on the encapsulation layer, and touch electrodes arranged between the plurality of inorganic insulating layers and forming a mutual capacitance with each other.

According to an embodiment of the present disclosure, the display panel may further include a black matrix overlapping with the touch electrodes in a thickness direction of the substrate, and color filters overlapping with the light-emitting areas.

According to an embodiment of the present disclosure, an electronic device includes a display device. The display device includes a first non-folding display area including a first display area, a second non-folding display area including a second display area and connected to a side of the first non-folding display area, a third non-folding display area including a third display area and connected to a side of the second non-folding display area, a fourth non-folding display area including a fourth display area and connected to a side of the third non-folding display area, a first folding display area located between the first non-folding display area and the second non-folding display area and being bendable, a second folding display area location between the second non-folding display area and the third non-folding display area and being bendable, and a third folding display area located between the third non-folding display area and the fourth non-folding display area and being bendable. The display device may operate in one of a first mode or a second mode. The first non-folding display area to the fourth non-folding display area may be arranged on a same plane as each other in the first mode and the first non-folding display area to the fourth non-folding display area may be arranged on different planes from each other in the second mode. The fourth non-folding display area may include a variably transparent layer that reflects or transmits a portion of light incident from outside depending on incidence surfaces.

According to an embodiment of the present disclosure, the fourth non-folding display area may further include a variably transparent area located around the fourth display area. The variably transparent layer may be located in the variably transparent area.

According to an embodiment of the present disclosure, the fourth non-folding display area may further include a reflective area located around the fourth display area, and a transmissive area located around the fourth display area and the reflective area. The variably transparent layer may be located in the reflective area.

These and other aspects, embodiments and advantages of the present disclosure will become immediately apparent to those of ordinary skill in the art upon review of the Detailed Description and Claims to follow.

According to some embodiments of the present disclosure, 3D images can be provided to a user by displaying a plurality of parallax images to the user in a folding mode of a display device.

According to some embodiments of the present disclosure, by using a variably transparent layer including a metal layer, it is possible to reduce the difficulty of the process of forming the variably transparent layer.

According to some embodiments of the present disclosure, by employing a reflective member including a cholesteric liquid crystal or a reflective member including an electrophoretic display, the variably transparent layer can be implemented in various ways.

It should be noted that effects of embodiments of the present disclosure are not necessarily limited to those described above and other effects of the present disclosure will be apparent to those skilled in the art from the following descriptions.

### BRIEF DESCRIPTION OF THE DRAWINGS

The above and other aspects and features of the present disclosure will become more apparent by describing in detail embodiments thereof with reference to the attached drawings, in which:

FIG. 1 is a front view for illustrating a display device according to an embodiment of the present disclosure;

FIG. 2 is a side view showing an example of the display panel of FIG. 1 according to an embodiment of the present disclosure;

FIG. 3 is a rear view showing an example of a housing of the display device of FIG. 1 according to an embodiment of the present disclosure;

FIG. 4 is a rear view showing another example of a housing of the display device of FIG. 1 according to an embodiment of the present disclosure;

FIG. 5 is a side view showing an example of the folding mode of the display device of FIG. 1 according to an embodiment of the present disclosure;

FIG. 6 is a side view for illustrating a folding mode of the display device of FIG. 5 according to an embodiment of the present disclosure;

FIG. 7 is a layout diagram for illustrating an example of the first non-folding display area of the display panel of FIG. 1 according to an embodiment of the present disclosure;

FIG. 8 is a layout diagram for illustrating an example of the second non-folding display area of the display panel of FIG. 1 according to an embodiment of the present disclosure;

FIG. 9 is a layout diagram for illustrating an example of the third non-folding display area of the display panel of FIG. 1 according to an embodiment of the present disclosure;

FIG. 10 is a layout diagram for illustrating an example of the fourth non-folding display area of the display panel of FIG. 1 according to an embodiment of the present disclosure;

FIG. 11 is a view for illustrating an image recognized by a user in the folding mode of the display device of FIG. 5 according to an embodiment of the present disclosure;

FIG. 12 is a cross-sectional view taken along line I-I′ of FIG. 10 according to an embodiment of the present disclosure;

FIG. 13 is a layout diagram for illustrating another example of the fourth non-folding display area of the display panel of FIG. 1 according to an embodiment of the present disclosure;

FIG. 14 is a cross-sectional view, taken along line J-J′ of FIG. 13 according to an embodiment of the present disclosure;

FIG. 15 is a cross-sectional view for illustrating an example of the variably transparent layer of FIG. 14 according to an embodiment of the present disclosure;

FIG. 16 is a cross-sectional view for illustrating another example of the variably transparent layer of FIG. 14 according to an embodiment of the present disclosure;

FIG. 17 is a side view showing another example of the folding mode of the display device of FIG. 1 according to an embodiment of the present disclosure;

FIG. 18 is a front view for illustrating a display device according to an embodiment of the present disclosure;

FIG. 19 is a side view showing an example of the display panel of FIG. 18 according to an embodiment of the present disclosure;

FIG. 20 is a layout diagram for illustrating the touch sensing layer of FIG. 19 according to an embodiment of the present disclosure;

FIG. 21 is an enlarged view of area A of FIG. 20 according to an embodiment of the present disclosure.

FIG. 22 is a cross-sectional view, taken along line K-K′ of FIG. 21 according to an embodiment of the present disclosure;

FIG. 23 is a cross-sectional view, taken along line K-K′ of FIG. 21 according to an embodiment of the present disclosure;

FIG. 24 is a graph showing transmittance versus wavelength for different thicknesses of silver (Ag) according to an embodiment of the present disclosure;

FIG. 25 is a graph showing transmittance versus wavelength for different thicknesses of Aluminum (Al) according to an embodiment of the present disclosure;

FIG. 26 is a block diagram for illustrating an electronic device including the display device according to an embodiment of the present disclosure;

FIG. 27 is a view showing examples of electronic devices including the display device of FIG. 26 according to some embodiments of the present disclosure.

### DETAILED DESCRIPTION OF EMBODIMENTS

Embodiments of the present disclosure will be described more fully hereinafter with reference to the accompanying drawings. Like reference numerals may refer to like elements throughout the specification and the accompanying drawings.

Herein, when two or more elements or values are described as being substantially the same as or about equal to each other, it is to be understood that the elements or values are identical to each other, the elements or values are equal to each other within a measurement error, or if measurably unequal, are close enough in value to be functionally equal to each other as would be understood by a person having ordinary skill in the art. For example, the term “about” as used herein is inclusive of the stated value and means within an acceptable range of deviation for the particular value as determined by one of ordinary skill in the art, considering the measurement in question and the error associated with measurement of the particular quantity (e.g., the limitations of the measurement system). For example, “about” may mean within one or more standard deviations as understood by one of the ordinary skill in the art. Further, it is to be understood that while parameters may be described herein as having “about” a certain value, according to embodiments, the parameter may be exactly the certain value or approximately the certain value within a measurement error as would be understood by a person having ordinary skill in the art. Other uses of these terms and similar terms to describe the relationship between components should be interpreted in a like fashion.

It will be understood that when a component, such as a film, a region, a layer, or an element, is referred to as being “on”, “connected to”, “coupled to”, or “adjacent to” another component, it can be directly on, connected, coupled, or adjacent to the other component, or intervening components may be present. When a component, such as a film, a region, a layer, or an element, is referred to as being “directly on”, “directly connected to”, “directly coupled to”, or “directly adjacent to” another component, no intervening components may be present. It will also be understood that when a component is referred to as “covering” another component, it can be the only component covering the other component, or one or more intervening components may also be covering the other component. Other words use to describe the relationship between elements may be interpreted in a like fashion.

It will be further understood that descriptions of features or aspects within each embodiment are available for other similar features or aspects in other embodiments, unless the context clearly indicates otherwise. Accordingly, all features and structures described herein may be mixed and matched in any desirable manner.

As used herein, the singular forms “a”, “an” and “the” are intended to include the plural forms as well, unless the context clearly indicates otherwise.

When a feature is said to extend, protrude, or otherwise follow a certain direction, it will be understood that the feature may follow said direction in the negative, such as the opposite direction. Accordingly, the feature is not limited to follow exactly one direction, and may follow along an axis formed by the direction, unless the context clearly indicates otherwise.

Hereinafter, embodiments of the present disclosure will be described in detail with reference to the accompanying drawings.

A display device that operates in first and second modes. The display device includes first to fourth non-folding display areas and first to third folding display areas. The first and fourth non-folding display areas may be arranged on a same plane as each other in the first mode. The first and fourth non-folding display areas may be arranged on different planes from each other in the second mode.

The fourth non-folding display area includes a half-transparent layer that may reflect or transmit some of lights incident from the outside depending on the incidence surfaces. The half-transparent layer may be include a metal layer having a thickness less than or equal to about 50 nm.

The display device generates 3D images to a user by displaying a plurality of parallax images to the user in the second mode.

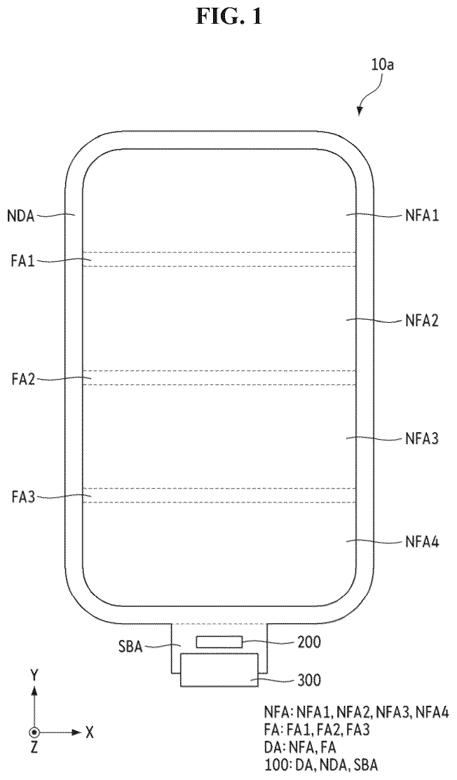

FIG. 1 is a front view for illustrating a display device according to an embodiment of the present disclosure.

In an embodiment, the display device 10a may be a light-emitting display device such as an organic light-emitting display device using organic light-emitting diodes, a quantum-dot light-emitting display device including a quantum-dot emissive layer, an inorganic light-emitting display device including an inorganic semiconductor, and a micro light-emitting display device using micro or nano light-emitting diodes (e.g., micro LEDs or nano LEDs). In the following description, an organic light-emitting display device is described as an example of the display device 10a. It is, however, to be understood that the embodiments of the present disclosure are not necessarily limited thereto.

Referring to FIG. 1, the display device 10a according to some embodiments of the present disclosure may include a display panel 100, a display driver circuit 200, and a display circuit board 300.

In an embodiment, the display panel 100 may be formed in a rectangular plane having shorter sides in a first direction (e.g., the x-axis direction) and longer sides in a second direction (e.g., the y-axis direction) intersecting the first direction (e.g., the x-axis direction). Each of the corners where the shorter sides in the first direction (e.g., the x-axis direction) meet the longer sides in the second direction (e.g., the y-axis direction) may be rounded with a predetermined curvature or may be a right angle. The shape of the display panel 100 when viewed from the top is not necessarily limited to a quadrangular shape, but may be formed in a different polygonal shape, a circular shape, or an elliptical shape. The display panel 100 may be formed flat, but embodiments of the present disclosure are not necessarily limited thereto. For example, the display panel 100 may be formed at left and right ends, and may include a curved portion having a constant curvature or a varying curvature. In addition, in an embodiment the display panel 100 may be flexible so that it can be curved, bent, folded or rolled.

The display panel 100 may include a display area DA, a non-display area NDA and a subsidiary area SBA.

The display area DA may include pixels for displaying images. The non-display area NDA may be formed around the display area DA (e.g., in a plan view). In an embodiment, the subsidiary area SBA may protrude from one side of the non-display area NDA in the opposite direction of the second direction (e.g., the −y-axis direction).

In an embodiment, the display area DA may include a first non-folding display area NFA1, a second non-folding display area NFA2, a third non-folding display area NFA3, a fourth non-folding display area NFA4, a first folding display area FA1, a second folding display area FA2, and a third folding display area FA3. However, embodiments of the present disclosure are not necessarily limited thereto and the respective number of the non-folding display areas and the folding display areas may vary. For example, in some embodiments the number of the non-folding display areas may be less than or equal to three or greater than or equal to five. The number of folding display areas may be less than or equal to two or greater than or equal to four.

The first to fourth non-folding display areas NFA1 to NFA4 may be non-deformable areas of the display area DA. On the contrary, the first folding display area to the third folding display area FA1 to FA3 may be bendable or otherwise deformable.

As shown in FIG. 1, a state in which the first folding display area to the third folding display area FA1 to FA3 are not bent and the display panel 100 forms a rectangular plane may be defined as a first mode (e.g., a non-folding mode). For example, in the first mode, the first non-folding display area to the fourth non-folding display area NFA1 to NFA4 may be arranged on the same plane as each other in the first mode. In some embodiments, in the first mode, the first non-folding display area to the fourth non-folding display area NFA1 to NFA4 and the first folding display area to the third folding display area FA1 to FA3 may emit light.

In an embodiment, the first non-folding display area NFA1 may be located on the upper side in the display device 10a (e.g., in the y-axis direction). In an embodiment, the upper side, left side and right side of the first non-folding display area NFA1 (e.g., in a plan view) may be in direct contact with the non-display area NDA. The lower side of the first non-folding display area NFA1 (e.g., in the −y-axis direction) may be in direct contact with the first folding display area FA1.

The second non-folding display area NFA2 may be located on the lower side of the first non-folding display area NFA1 (e.g., in the −y-axis direction). The upper side of the second non-folding display area NFA2 (e.g., in the y axis direction) may be in direct contact with the first folding display area FA1. The left side and right side of the second non-folding display area NFA2 (e.g., in the-x-axis direction and x-axis direction, respectively) may be in direct contact with the non-display area NDA. The lower side of the second non-folding display area NFA2 (e.g., in the-y-axis direction) may be in direct contact with the second folding display area FA2.

The third non-folding display area NFA3 may be located on the lower side of the second non-folding display area NFA2 (e.g., in the −y-axis direction). The upper side of the third non-folding display area NFA3 (e.g., in the y-axis direction) may be in direct contact with the second folding display area FA2. The left side and right side of the third non-folding display area NFA3 (e.g., in the −x-axis direction and the x-axis direction, respectively) may be in direct contact with the non-display area NDA. The lower side of the third non-folding display area NFA3 may be in direct contact with the third folding display area FA3.

The fourth non-folding display area NFA4 may be located on the lower side in the display device 10a (e.g., in the −y-axis direction). The upper side of the fourth non-folding display area NFA4 may be in direct contact with the third folding display area FA3. The left side, the right side and the lower side (e.g., in a plan view) of the fourth non-folding display area NFA4 may be in direct contact with the non-display area NDA.

Although the subsidiary area SBA is unfolded in the example shown in FIG. 1, the subsidiary area SBA may be bent and may be located on the lower surface of the display panel 100. When the subsidiary area SBA is bent, it may overlap with the display area DA and the non-display area NDA in the thickness direction (e.g., the z-axis direction) of the substrate SUB. The display driver circuit 200 may be located in the subsidiary area SBA.

The display driver circuit 200 may generate signals and voltages for driving the display panel 100. In an embodiment, the display driver circuit 200 may be implemented as an integrated circuit (IC) and may be attached to the display panel 100 by a chip on glass (COG) technique, a chip on plastic (COP) technique, or an ultrasonic bonding. However, embodiments of the present disclosure are not necessarily limited thereto. For example, in some embodiments the display driver circuit 200 may be attached on the display circuit board 300 by the chip-on-film (COF) technique.

The display circuit board 300 may be attached to one end of the subsidiary area SBA of the display panel 100. Accordingly, the display circuit board 300 may be electrically connected to the display panel 100 and the display driver circuit 200. The display panel 100 and the display driver circuit 200 may receive digital video data, timing signals, and driving voltages through the display circuit board 300. In an embodiment, the display circuit board 300 may be a flexible printed circuit board, a printed circuit board, or a flexible film such as a chip on film.

To reduce external light from being reflected by metal lines and metal electrodes of the display panel 100, the display panel 100 may include a color filter layer including color filters. Alternatively, the display panel 100 may include an anti-reflection member such as a polarizing plate.

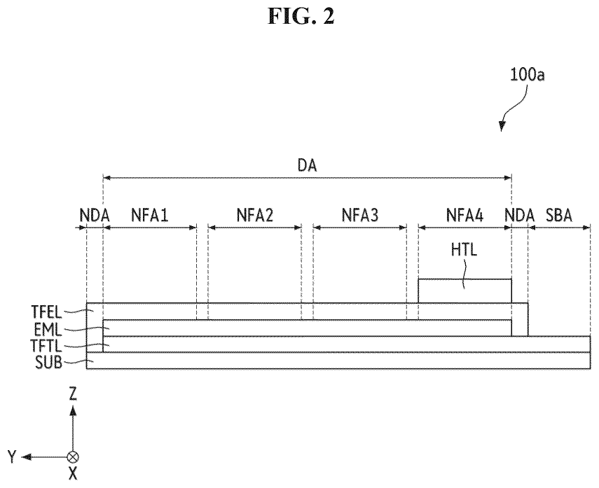

FIG. 2 is a side view showing an example of the display panel of FIG. 1.

Referring to FIG. 2, in an embodiment a display layer 100a may include a substrate SUB, a thin-film transistor layer TFTL, a light-emitting material layer EML, an encapsulation layer TFEL and a variably transparent layer HTL.

The thin-film transistor layer TFTL may be located on the substrate SUB (e.g., disposed directly thereon in the z-axis direction). The thin-film transistor layer TFTL may be located in the display area DA, the non-display area NDA and the subsidiary area SBA. The thin-film transistor layer TFTL may include transistors.

The light-emitting material layer EML may be located on the thin-film transistor layer TFTL (e.g., disposed directly thereon in the z-axis direction). The light-emitting material layer EML may be located in the display area DA. The light-emitting material layer EML may include light-emitting elements arranged in light-emitting areas.

The encapsulation layer TFEL may be located on (e.g., disposed directly thereon) the light-emitting material layer EML. The encapsulation layer TFEL may be located in the display area DA and the non-display area NDA. The encapsulation layer TFEL may include at least one inorganic film and at least one organic film for encapsulating the light-emitting material layer.

The variably transparent layer HTL may be located on the encapsulation layer TFEL (e.g., disposed directly thereon in the z-axis direction). The variably transparent layer HTL may be arranged in the fourth non-folding display area NFA4. The variably transparent layer HTL may reflect or transmit some of lights incident from the outside (e.g., the external environment) depending on the incidence surfaces.

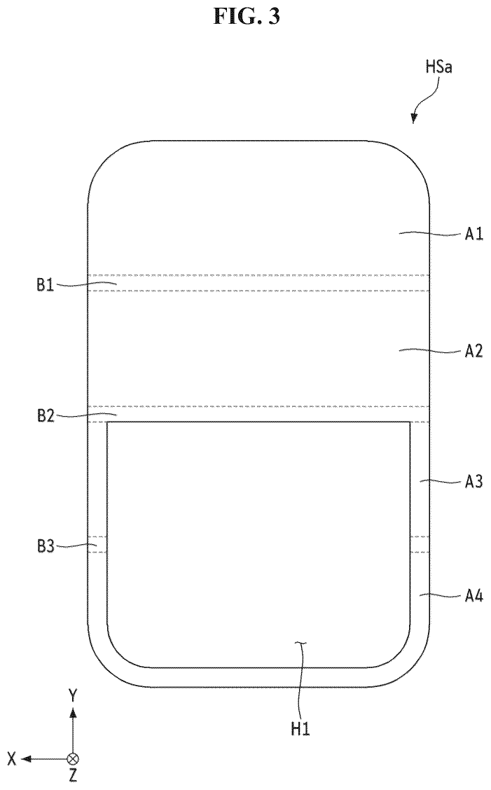

FIG. 3 is a rear view showing an example of a housing of the display device of FIG. 1.

Referring to FIG. 3, in an embodiment a housing HSa may include a first non-folding housing portion A1, a second non-folding housing portion A2, a third non-folding housing portion A3, a fourth non-folding housing portion A4, a first folding housing portion B1, a second folding housing portion B2, and a third folding housing portion B3

The first non-folding housing portion A1 may be located on the upper side in the display device 10a (e.g., in the y-axis direction). The first non-folding housing portion A1 may be located on a surface of the first non-folding display area NFA1. In an embodiment, the area (e.g., in a plan view) of the first non-folding housing portion A1 may be greater than or equal to the area (e.g., in a plan view) of the first non-folding display area NFA1.

The first folding housing portion B1 may be in direct contact with the lower side of the first non-folding housing portion A1 (e.g., in the −y-axis direction). The first folding housing portion B1 may be located on a surface of the first folding display area FA1. The first folding housing portion B1 may be located between the first non-folding housing portion A1 and the second non-folding housing portion A2 (e.g., in the −y-axis direction). In an embodiment, the area (e.g., in a plan view) of the first folding housing portion B1 may be greater than or equal to the area (e.g., in a plan view) of the first folding display area FA1. The first folding housing portion B1 may be bent.

The second non-folding housing portion A2 may be in direct contact with the lower side of the first folding housing portion B1 (e.g., in the −y-axis direction). The first non-folding housing portion A2 may be located on a surface of the second non-folding display area NFA2. In an embodiment, the area (e.g., in a plan view) of the second non-folding housing portion A2 may be greater than or equal to the area (e.g., in a plan view) of the second non-folding display area NFA2.

The second folding housing portion B2 may be in direct contact with the lower side of the second non-folding housing portion A2 (e.g., in the −y-axis direction). The second folding housing portion B2 may be located on a surface of the second folding display area FA2. The second folding housing portion B2 may be located between the second non-folding housing portion A2 and the third non-folding housing portion A3 (e.g., in the −y-axis direction). In an embodiment, the area (e.g., in a plan view) of the second folding housing portion B2 may be greater than or equal to the area (e.g., in a plan view) of the second folding display area FA2. The second folding housing portion B2 may be bent.

The third non-folding housing portion A3 may be in direct contact with the lower side of the second folding housing portion B2 (e.g., in the −y-axis direction). The third non-folding housing portion A3 may be located on a part of (e.g., some of) the edges (e.g., edges on the left and right sides in the x-axis direction and −x-axis direction, respectively) of the third non-folding display area NFA3. The third non-folding housing portion A3 may be formed at the opposite ends of the second folding housing portion B2 (e.g., in the x-axis direction and −x-axis direction).

The third folding housing portion B3 may be in direct contact with the lower side of the third non-folding housing portion A3 (e.g., in the −y-axis direction). The third folding housing portion B3 may be located on a part of (e.g., some of) the edges (e.g., edges on the left and right sides in the x-axis direction and −x-axis direction, respectively) of the third folding display area FA3. The third folding housing portion B3 may be located between the third non-folding housing portion A3 and the fourth non-folding housing portion A4 (e.g., in the −y-axis direction). The third folding housing portion B3 may be formed on a side of the third non-folding housing portion A3. The third folding housing portion B3 may be bent (e.g., may be bendable).

The fourth non-folding housing portion A4 may be in direct contact with the lower side of the third folding housing portion B3 (e.g., in the −y-axis direction). The fourth non-folding housing portion A4 may be located on a part of the edges (e.g., edges on the left and right sides and the lower side in a plan view) of the fourth non-folding display area NFA4. The fourth non-folding housing portion A4 may be connected with a side of the third folding housing portion B3.

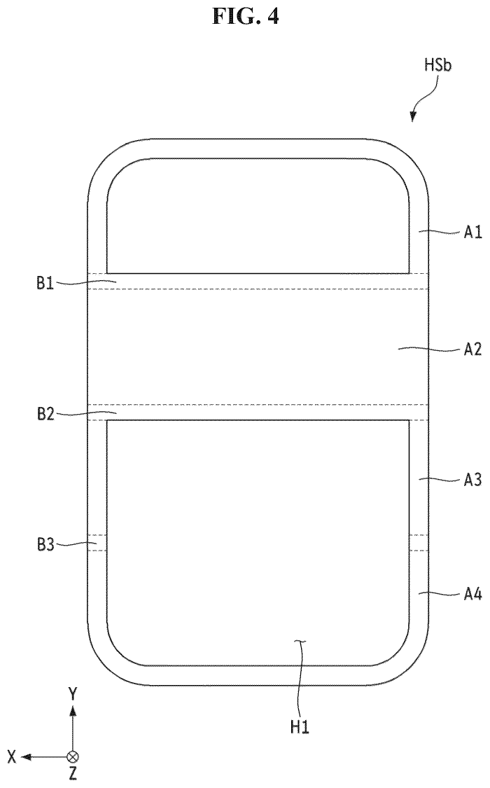

FIG. 4 is a rear view showing another example of a housing of the display device of FIG. 1. The following description will focus on differences and the redundant description will be omitted for economy of explanation.

Referring to FIG. 4, in an embodiment a housing HSb may include a first non-folding housing portion A1, a second non-folding housing portion A2, a third non-folding housing portion A3, a fourth non-folding housing portion A4, a first folding housing portion B1, a second folding housing portion B2, and a third folding housing portion B3.

The example shown in FIG. 4 is different from the example of FIG. 3 in that the first non-folding housing portion A1 of FIG. 4 may be placed on a part of (e.g., some of) the edges (e.g., the upper edge and the two side edges in a plan view) of the first non-folding display area NFA1. For example, the upper and lower surfaces of the first non-folding display area NFA1 may be exposed to the outside (e.g., the external environment).

The first folding housing portion B1 may connect between the opposite ends of the first non-folding housing portion A1 (e.g., in the x-axis direction and the −x-axis direction). The first folding housing portion B1 may be located on a surface of the first folding display area FA1. The first folding housing portion B1 may be located between the first non-folding housing portion A1 and the second non-folding housing portion A2 (e.g., in the −y-axis direction). In an embodiment, the area (e.g., in a plan view) of the first folding housing portion B1 may be greater than or equal to the area (e.g., in a plan view) of the first folding display area FA1. The first folding housing portion B1 may be bent (e.g., may be bendable).

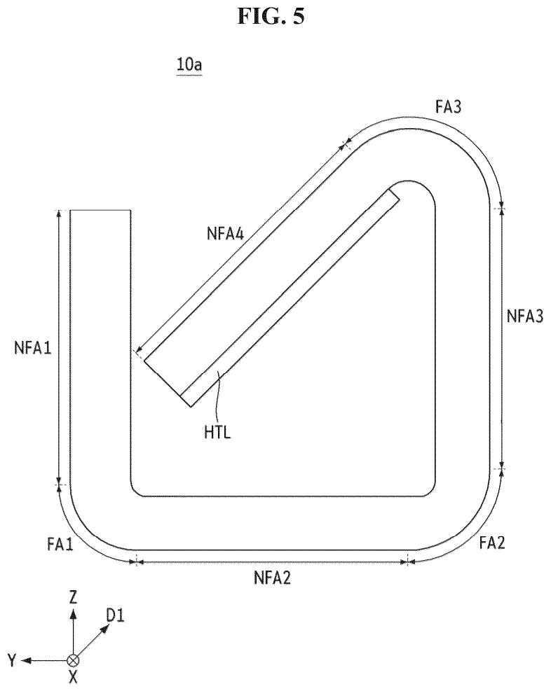

FIG. 5 is a side view showing an example of the folding mode of the display device of FIG. 1.

In FIG. 5 and the subsequent drawings, the subsidiary area SBA is not depicted for convenience of illustration. For example, the subsidiary area SBA may be bent and accommodated inside the housings HSa and HSb.

Referring to FIG. 5, the display device 10a may operate in a second mode (e.g., a folding mode) in which the first folding display area FA1, the second folding display area FA2, and the third folding display area FA3 are bent (e.g., in a bent orientation). For example, the first to fourth non-display areas NFA1 to NFA4 may be arranged on different planes from each other in the second mode.

The first non-folding display area NFA1 may be arranged to extend in the third direction (e.g., the z-axis direction). The second non-folding display area NFA2 may be arranged to extend in the second direction (e.g., the y-axis direction). The third non-folding display area NFA3 may be arranged to extend in the third direction (e.g., the z-axis direction). The third non-folding display area NFA3 may be arranged parallel to the first non-folding display area NFA1. The fourth non-folding display area NFA4 may be arranged to extend in a fourth direction D1 intersecting the second direction (e.g., the y-axis direction) and the third direction (e.g., the z-axis direction). For example, in an embodiment the fourth direction D1 may form the angle of 45° with respect to the second direction (e.g., the y-axis direction) and the third direction (e.g., the z-axis direction). The variably transparent layer HTL of the fourth non-folding display area NFA4 may face the third non-folding display area NFA3 and the second non-folding display area NFA2.

In an embodiment, the length of the first non-folding display area NFA1 in the third direction (e.g., the z-axis direction) may be substantially equal to the length of the third non-folding display area NFA3 in the third direction (e.g., the z-axis direction). The length of the first non-folding display area NFA1 in the third direction (e.g., the z-axis direction) may be substantially equal to the length of the second non-folding display area NFA2 in the second direction (e.g., the y-axis direction). The length of the fourth non-folding display area NFA4 in the fourth direction D1 may be greater than the length of the first non-folding display area NFA1 in the third direction (e.g., the z-axis direction). The length of the fourth non-folding display area NFA4 in the fourth direction D1 may be greater than the length of the second non-folding display area NFA2 in the second direction (e.g., the y-axis direction). The length of the fourth non-folding display area NFA4 in the fourth direction D1 may be greater than the length of the third non-folding display area NFA3 in the third direction (e.g., the z-axis direction).

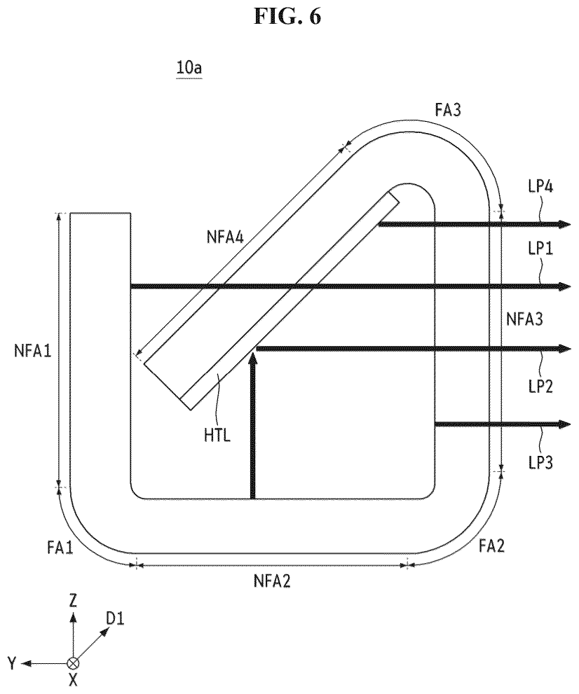

FIG. 6 is a side view for illustrating a folding mode of the display device of FIG. 5. The following description will focus on differences and the redundant description will be omitted for economy of explanation.

Referring to FIG. 6, in an embodiment the first non-folding display area NFA1 may be transparent or opaque. The second non-folding display area NFA2 may be opaque. The third non-folding display area NFA3 may be transparent (e.g., a transparent display). The fourth non-folding display area NFA4 may be transparent (e.g., a transparent display).

A first light LP1 output from the first non-folding display area NFA1 may be transmit through the fourth non-folding display area NFA4. Subsequently, the light transmitted through the fourth non-folding display area NFA4 may be transmitted through the third non-folding display area NFA3. Accordingly, the first light LP1 can be recognized (e.g., visualized) by a user located on the opposite side of the display device 10a in the second direction (e.g., the −y-axis direction).

According to some embodiments, the first non-folding display area NFA1 may be transparent. Accordingly, an object or background located on the side of the first non-folding display area NFA1 in the second direction (e.g., the y-axis direction) can be recognized (e.g., visualized) by the user like the first light LP1.

A second light LP2 output from the second non-folding display area NFA2 may be reflected off the variably transparent layer HTL of the fourth non-folding display area NFA4. Accordingly, the second light LP2 can be recognized (e.g., visualized) by the user located on the opposite side in the second direction (e.g., the −y-axis direction).

A third light LP3 output from a surface of the third non-folding display area NFA3 may transmit through the third non-folding display area NFA3. Accordingly, the third light LP3 can be recognized (e.g., visualized) by the user located on the opposite side in the second direction (e.g., the −y-axis direction).

A fourth light LP4 output from the fourth non-folding display area NFA4 may transmit through the third non-folding display area NFA3. Accordingly, the fourth light LP4 can be recognized (e.g., visualized) by the user located on the opposite side in the second direction (e.g. the −y-axis direction).

The first to fourth lights LP1 to LP4 may be seen by the user located on the opposite side in the second direction (e.g., the −y-axis direction). In an embodiment, in the second mode the first and fourth lights LP1, LP4 may be transmitted so that the user recognizes (e.g., visualizes) the first light LP1 as being adjacent to the display areas of the second and third non-display areas NDA2, NDA3. It should be noted that the first to fourth lights LP1 to LP4 are output from different positions and thus the distances from the positions to the user's eyes may be different.

For example, the user may feel (e.g., perceive) that the third light LP3 output from the third non-folding display area NFA3 is closest. The user may feel that the fourth light LP4 output from the fourth non-folding display area NFA4 is located more distant than the third light LP3. The user may feel that the second light LP2 output from the second non-folding display area NFA2 is located more distant than the third light LP3. The user may feel that the first light LP1 output from the first non-folding display area NFA1 is most distant.

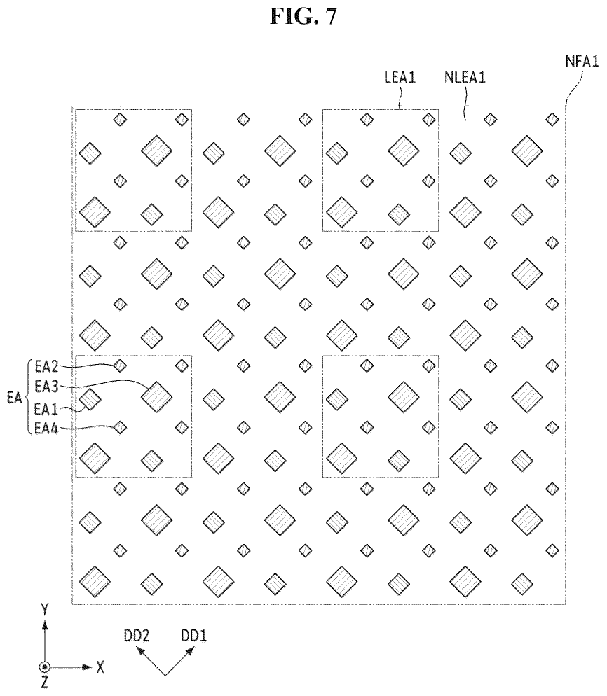

FIG. 7 is a layout diagram for illustrating an example of the first non-folding display area of the display panel of FIG. 1.

Referring to FIG. 7, in an embodiment the first non-folding display area NFA1 may include first display areas LEA1 and a first peripheral display area NLEA1 arranged around the first display areas LEA1 (e.g., in a plan view). The first display areas LEA1 and the first peripheral display area NLEA1 may include a plurality of light-emitting areas EA.

The first display areas LEA1 may be arranged periodically. For example, in an embodiment each of the first display areas LEA1 may include two first light-emitting areas EA1, two second light-emitting areas EA2, two third light-emitting areas EA3, and two fourth light-emitting areas EA4. Between one first display area LEA1 and another first display area LEA1 adjacent thereto, two first light-emitting areas EA1, two second light-emitting areas EA2, two third light-emitting areas EA3, and two fourth light-emitting areas EA4 may be arranged. One first display area LEA1 and another first display area LEA1 may be arranged such that they are spaced apart from each other in the first direction (e.g., the x-axis direction) and the second direction (e.g., the y-axis direction). However, embodiments of the present disclosure are not necessarily limited thereto and the number of the plurality of light-emitting areas may vary and the arrangement of the plurality of light-emitting areas may vary.

The first light-emitting area EA1 may emit light of a first color. In an embodiment, the first color is red, and the peak wavelength of light of the first color may be included in the wavelength range of approximately 600 nm to 750 nm.

The second light-emitting area EA2 may emit light of a second color. In an embodiment, the second color is green, and the peak wavelength of light of the second color may be included in the wavelength range of approximately 500 nm to 570 nm.

The third light-emitting area EA3 may emit light of a third color. In an embodiment, the third color is blue, and the peak wavelength of light of the third color may be included in the wavelength range of approximately 430 nm to 490 nm.

The fourth light-emitting area EA4 may emit light of the second color like the second light-emitting area EA2. However, embodiments of the present disclosure are not necessarily limited thereto and the colors emitted by the light-emitting areas EA may vary.

For example, in an embodiment the light-emitting areas EA may be arranged in the Pentile™ matrix. The first light-emitting area EA1 may be spaced apart from the second light-emitting area EA2 in a direction opposite to the first diagonal direction (e.g., the −DD1 direction). The first light-emitting area EA1 may be spaced apart from the third light-emitting areas EA3 in a direction opposite to the the first direction (e.g., the −x-axis direction). The first light-emitting area EA1 may be spaced apart from the fourth light-emitting area EA4 in the second diagonal direction (e.g., the DD2 direction). The second light-emitting area EA2 may be spaced apart from the third light-emitting area EA3 in the second diagonal direction (e.g., the DD2 direction). The second light-emitting area EA2 may be spaced apart from the fourth light-emitting areas EA4 in the second direction (e.g., the y-axis direction). The third light-emitting area EA3 may be spaced apart from the fourth light-emitting area EA4 in the first diagonal direction (e.g., the DD1 direction).

Although the shapes of the light-emitting areas EA when viewed from the top (e.g., in a plan view) are rhombus in the drawings, embodiments of the present disclosure are not necessarily limited thereto. The shape of the light-emitting areas EA when viewed from the top may be modified in a variety of ways shapes, such as circular, elliptical, and polygonal shapes.

The light-emitting areas EA may have different areas (e.g., in a plan view) from each other. For example, in an embodiment the first light-emitting area EA1 may be larger than the second light-emitting area EA2 and smaller than the third light-emitting area EA3. The size of the second light-emitting area EA2 may be equal to the size of the fourth light-emitting area EA4. It should be understood, however, that the embodiments of the present disclosure are not limited thereto. The size of the light-emitting areas EA may be adjusted as desired.

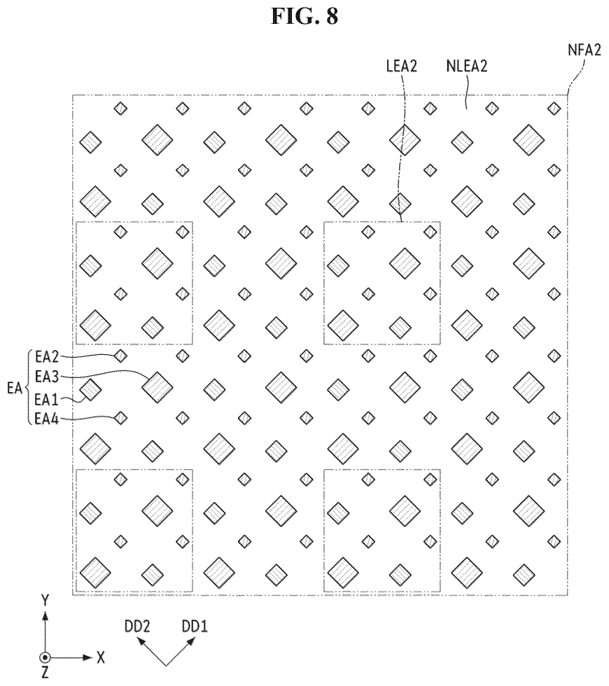

FIG. 8 is a layout diagram for illustrating an example of the second non-folding display area of the display panel of FIG. 1. The following description will focus on differences and the redundant description will be omitted for economy of explanation.

Referring to FIG. 8, the second non-folding display area NFA2 may include second display areas LEA2 and a second peripheral display area NLEA2 arranged around the second display areas LEA2 (e.g., in a plan view). The second display areas LEA2 and the second peripheral display area NLEA2 may include a plurality of light-emitting areas EA.

The second display areas LEA2 may be arranged periodically. For example, in an embodiment each of the second display areas LEA2 may include two first light-emitting areas EA1, two second light-emitting areas EA2, two third light-emitting areas EA3, and two fourth light-emitting areas EA4. Between one second display area LEA2 and another second display area LEA2 adjacent thereto, two first light-emitting areas EA1, two second light-emitting areas EA2, two third light-emitting areas EA3, and two fourth light-emitting areas EA4 may be arranged. One second display area LEA2 and another second display area LEA2 may be arranged such that they are spaced apart from each other in the first direction (e.g., the x-axis direction) and the second direction (e.g., the y-axis direction).

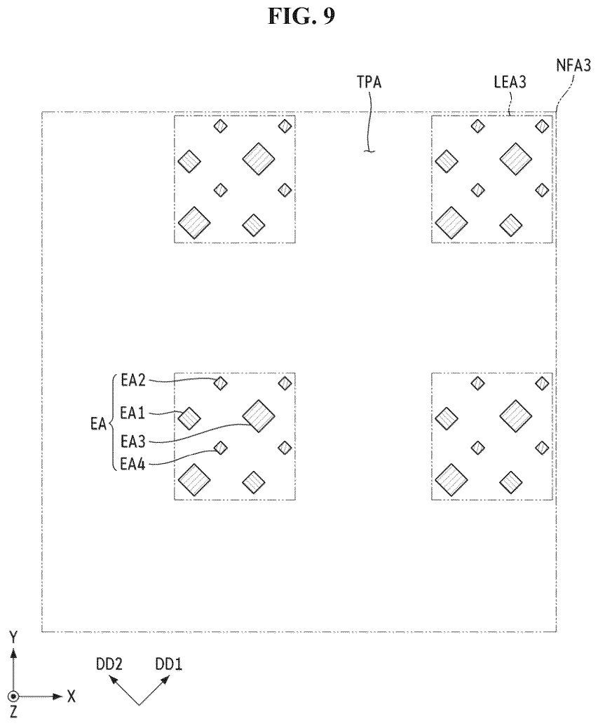

FIG. 9 is a layout diagram for illustrating an example of the third non-folding display area of the display panel of FIG. 1. The following description will focus on differences and the redundant description will be omitted for economy of explanation.

Referring to FIG. 9, the third non-folding display area NFA3 may include third display areas LEA3 and a transparent area TPA arranged around the third display areas LEA3 (e.g., in a plan view). The third display areas LEA3 may include a plurality of light-emitting areas EA. Light-emitting areas EA are not disposed in the transparent area TPA so that external light is transmitted.

The third display areas LEA3 may be arranged periodically. For example, one third display area LEA3 may be spaced apart from another third display area LEA3 in the first direction (e.g., the x-axis direction) or the second direction (e.g., the y-axis direction) by the size of the third display area LEA3.

For example, in an embodiment each of the third display areas LEA3 may include two first light-emitting areas EA1, two second light-emitting areas EA2, two third light-emitting areas EA3, and two fourth light-emitting areas EA4.

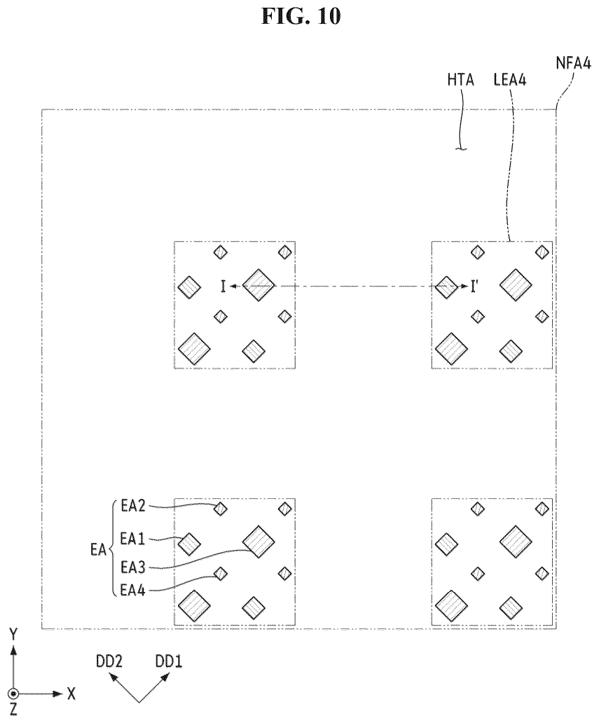

FIG. 10 is a layout diagram for illustrating an example of the fourth non-folding display area of the display panel of FIG. 1. The following description will focus on differences and the redundant description will be omitted for economy of explanation.

Referring to FIG. 10, the fourth non-folding display area NFA4 may include fourth display areas LEA4 and a variably transparent area HTA arranged around the fourth display areas LEA4 (e.g., in a plan view). The variably transparent layer HTL may be located in the variably transparent area HTA. The fourth display areas LEA4 may include a plurality of light-emitting areas EA.

The fourth display areas LEA4 may be arranged periodically. For example, in an embodiment one fourth display area LEA4 may be spaced apart from another fourth display area LEA4 in the first direction (e.g., the x-axis direction) or the second direction (e.g., the y-axis direction) by the size of the fourth display area LEA4.

For example, in an embodiment each of the fourth display areas LEA4 may include two first light-emitting areas EA1, two second light-emitting areas EA2, two third light-emitting areas EA3, and two fourth light-emitting areas EA4.

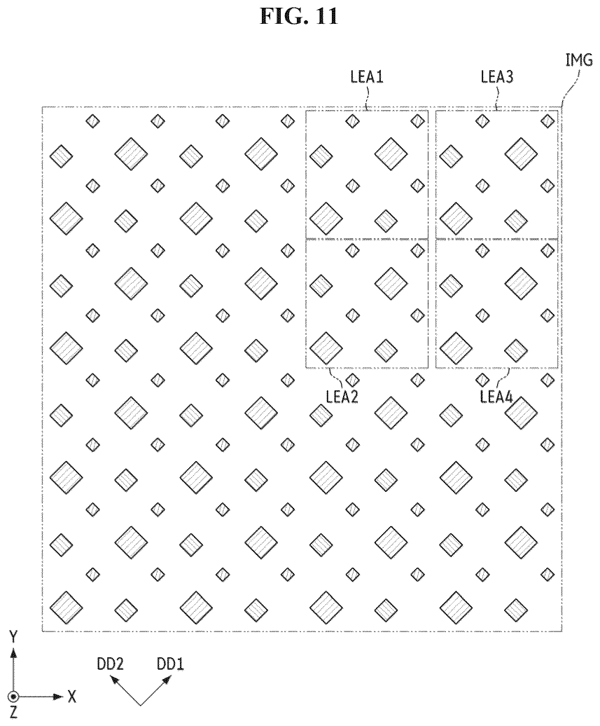

FIG. 11 is a view for illustrating an image recognized by a user in the folding mode of the display device of FIG. 5. The following description will focus on differences and the redundant description will be omitted for economy of explanation.

Referring to FIG. 11, an image IMG recognized by a user may include first to fourth display areas LEA1 to LEA4. The first to fourth display areas LEA1 to LEA4 may be arranged adjacent to each other without overlapping each other (e.g., in a plan view).

For example, in an embodiment the first display area LEA1 may be placed adjacent to the second display area LEA2 in the second direction (e.g., the y-axis direction). The first display area LEA1 may be arranged adjacent to the third display area LEA3 in a direction opposite to the first direction (e.g., the −x-axis direction). The first display area LEA1 may be arranged adjacent to the fourth display area LEA4 in the second diagonal direction DD2. The second display area LEA2 may be arranged adjacent to the third display area LEA3 in a direction opposite to the first diagonal direction DD1 (e.g., the −DD1 direction). The third display area LEA3 may be arranged adjacent to the fourth display area LEA4 in the second direction (e.g., the y-axis direction).

Since the image IMG includes the first display area to the fourth display area LEA1 to LEA4, the user can recognize image displayed by all of the first to the fourth non-folding display areas NFA1 to NFA4.

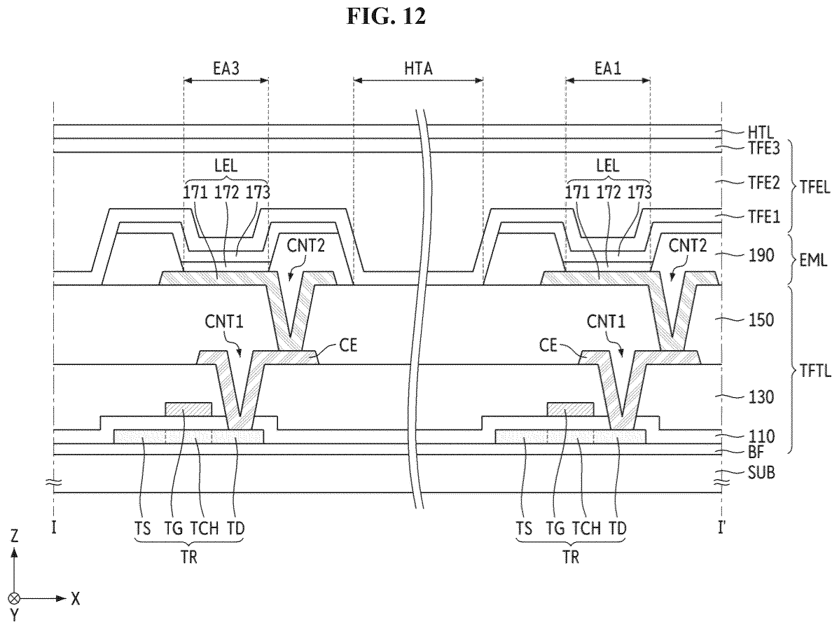

FIG. 12 is a cross-sectional view taken along line I-I′ of FIG. 10. The following description will focus on differences and the redundant description will be omitted for economy of explanation.

Referring to FIG. 12, in an embodiment a display layer 100a may include a substrate SUB, a thin-film transistor layer TFTL, a light-emitting material layer EML, an encapsulation layer TFEL and a variably transparent layer HTL.

In an embodiment, the substrate SUB may be made of an insulating material such as glass, quartz and a polymer resin. Alternatively, the substrate SUB may include a metallic material. The substrate SUB may be a rigid substrate or a flexible substrate that can be bent, folded, rolled, deformed, etc. In an embodiment in which the substrate SUB is a flexible substrate, it may be formed of, but is not necessarily limited to, polyimide (PI).

The thin-film transistor layer TFTL may be located on the substrate SUB (e.g., in the z-axis direction). The thin-film transistor layer TFTL may include thin-film transistors TR for each light-emitting pixel, connecting electrodes CE, and a plurality of insulating films.

In an embodiment, a buffer film BF may be located on the substrate SUB (e.g., disposed directly thereon in the z-axis direction). In an embodiment, the buffer film BF may be composed of multiple inorganic films stacked on one another alternately. For example, the buffer layer BF may be composed of multiple layers in which one or more inorganic layers of a silicon nitride layer, a silicon oxynitride layer, a silicon oxide layer, a titanium oxide layer and an aluminum oxide layer are alternately stacked on one another (e.g., in the z-axis direction).

The active layer of each of the thin-film transistors TR may be located on the buffer film BF. The active layer includes a channel TCH, a source electrode TS and a drain electrode TD.

A gate insulator 110 may be located on the active layer. In an embodiment, the gate insulator 110 may be formed as an inorganic insulating film, for example, a silicon nitride film (SiNx), a silicon oxide film (SiOx), a silicon nitride oxide film (SiON), a titanium oxide film (TiOx), or an aluminum oxide film (AlOx).

The gate electrode TG of the transistor TR may be located on the gate insulator 110 (e.g., disposed directly thereon in the z-axis direction). The gate electrode TG may overlap with the channel TCH in a third direction (e.g., the z-axis direction). In an embodiment, the gate electrode TG may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

An interlayer dielectric layer 130 may be located on the gate electrode TG of the transistor TR (e.g., disposed directly thereon in the z-axis direction). In an embodiment, the interlayer dielectric film 130 may be formed of an inorganic layer, for example, a silicon nitride layer, a silicon oxynitride layer, a silicon oxide layer, a titanium oxide layer, or an aluminum oxide layer. The interlayer dielectric film 130 may include a plurality of inorganic films.

A first source-metal layer may be arranged on the interlayer dielectric film 130 (e.g., disposed directly thereon in the z-axis direction). The first source metal layer includes the connecting electrodes CE. In an embodiment, the connecting electrodes CE may be connected to the drain electrode TD of the transistor TR through a first contact hole CT1 penetrating the gate insulator 110 and the interlayer dielectric layer 130. In an embodiment, the connecting electrodes CE may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

A protective film 150 may be arranged on (e.g., disposed directly thereon) the first source metal layer to provide a flat surface over the transistor TR and protect the transistor TR. In an embodiment, the protective film 150 may be implemented as an organic layer such as an acryl resin, an epoxy resin, a phenolic resin, a polyamide resin and a polyimide resin.

The light-emitting material layer EML including a light-emitting element LEL and a pixel-defining layer 190 may be arranged on the protective film 150. Each of the light-emitting elements LEL may include a pixel electrode 171, an emissive layer 172, and a common electrode 173.

In an embodiment, a pixel electrode layer may be located on the protective film 150 (e.g., disposed directly thereon in the z-axis direction). The pixel electrode layer may include the pixel electrode 171. In an embodiment, the pixel electrode 171 may be connected to a connecting electrode CE through a second contact hole CNT2 penetrating the protective film 150. In an embodiment, in the top-emission architecture where light exits from the emissive layer 172 toward the common electrode 173, the pixel electrode 171 may be made up of a single layer of molybdenum (Mo), titanium (Ti), copper (Cu) or aluminum (Al), or may be made up of a stack structure of aluminum and titanium (Ti/Al/Ti), a stack structure of aluminum and ITO (ITO/Al/ITO), an APC alloy and a stack structure of APC alloy and ITO (ITO/APC/ITO) in order to increase the reflectivity. The APC alloy is an alloy of silver (Ag), palladium (Pd) and copper (Cu).

The pixel-defining layer 190 may be located on a portion of a pixel electrode 171. The pixel-defining layer 190 may define the light-emitting areas EA of the light-emitting pixels. The pixel-defining layer 190 may be formed on the protective film 150 to expose a portion of the pixel electrodes 171. For example, in an embodiment the pixel-defining layer 190 may cover edges of the pixel electrodes 171 and expose a central portion of the pixel electrodes 171. In an embodiment, the pixel-defining layer 190 may be formed of an organic layer such as an acryl resin, an epoxy resin, a phenolic resin, a polyamide resin and a polyimide resin.

The emissive layer 172 may be located on the pixel electrode 171. The emissive layer 172 may be an organic emissive layer including an organic material. In an embodiment, the emissive layer 172 may include a hole transporting layer, an organic light-emitting layer and an electron transporting layer. When a voltage is applied to the pixel electrode and a cathode voltage is applied to the common electrode 173 through a thin-film transistor TR of the thin-film transistor layer TFTL, the holes and electrons move to the organic emissive layer 172 through the hole transporting layer and the electron transporting layer, respectively, such that they combine in the organic emissive layer to emit light. The pixels of the light-emitting material layer EML may be located in the display area DA.

The common electrode 173 may be located on the pixel-defining layer 190 and the emissive layer 172. The common electrode 173 may be formed to cover the emissive layer 172. In an embodiment, the common electrode 173 may be a common layer formed across the light-emitting areas EA.

Depending on the direction of the cross section, there may be a region between the light-emitting areas EA where the common electrode 173 and the pixel-defining layer 190 are not arranged. The region where the common electrode 173 and the pixel-defining layer 190 are not arranged may be defined as the variably transparent area HTA. Since the common electrode 173 and the pixel-defining layer 190 are not arranged in the variably transparent area HTA, light traveling from the outside may be transmitted. It should be noted, however, that some of the lights traveling from the outside may be transmitted or reflected in the variably transparent layer HTL described later.

The encapsulation layer TFEL may be arranged on the light-emitting material layer EML (e.g., in the z-axis direction). In an embodiment, the encapsulation layer TFEL may include a first inorganic encapsulation layer TFE1 and a second inorganic encapsulation layer TFE3 that serve to prevent oxygen or moisture from permeating into the light-emitting material layer EML. The first inorganic encapsulation layer TFE1 and the second inorganic encapsulation layer TFE3 may be, but is not necessarily limited to, a silicon nitride layer, a silicon oxynitride layer, a silicon oxide layer, a titanium oxide layer, or an aluminum oxide layer.

In addition, the encapsulation layer TFEL may include an organic encapsulation layer TFE2 that protects the light-emitting material layer EML from particles such as dust. The organic encapsulation layer TFE2 may be located between the first inorganic encapsulation layer TFE1 and the second inorganic encapsulation layer TFE3 (e.g., in the z-axis direction). In an embodiment, the organic encapsulation layer TFE2 may be, but is not necessarily limited to, an acryl resin, an epoxy resin, a phenolic resin, a polyamide resin, a polyimide resin, etc.

The encapsulation layer TFEL may be located in the display area DA as well as the non-display area NDA. Specifically, the encapsulation layer TFEL may cover the display area DA and the light-emitting material layer EML and may cover the thin-film transistor layer TFTL in the non-display area NDA.

The variably transparent layer HTL may be located on the encapsulation layer TFEL (e.g., disposed directly thereon in the z-axis direction). The variably transparent layer HTL may include a metal layer that reflects visible light. For example, in an embodiment the thickness of the metal layer may be less than or equal to about 50 nm. In an embodiment, the metal layer may include, but is not necessarily limited to, gold, silver, copper, or aluminum. As the thickness of the metal layer becomes smaller in nanometer units, the variably transparent layer HTL may have a transmittance. Therefore, the variably transparent layer that reflects or transmits visible light may be formed using a metal.

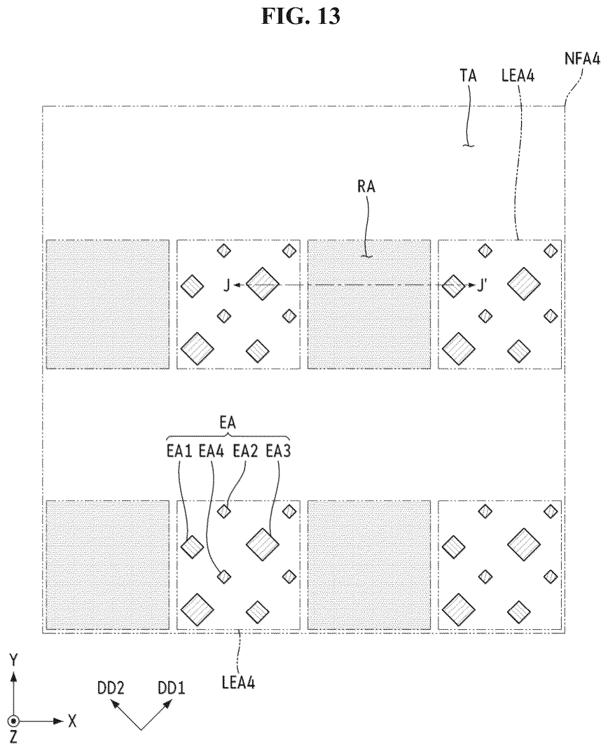

FIG. 13 is a layout diagram for illustrating another example of the fourth non-folding display area of the display panel of FIG. 1. The following description will focus on differences and the redundant description will be omitted for economy of explanation.

Referring to FIG. 13, the fourth non-folding display area NFA4 may include fourth display areas LEA4, reflective areas RA, and transmissive areas TA.

Although the fourth display areas LEA4 are adjacent to the reflective areas RA in the first direction (e.g., the x-axis direction) in the drawings, embodiments of the present disclosure are not necessarily limited thereto. The fourth display areas LEA4 may be adjacent to the reflective areas RA in the second direction (e.g., the y-axis direction), or may be adjacent to the first diagonal direction DD1 or the second diagonal direction DD2.

In addition, although the size (e.g., area in a plan view) of the reflective areas RA is equal to that of the fourth display areas LEA4 in the drawings, embodiments of the present disclosure are not necessarily limited thereto. The size (e.g., area in a plan view) of the reflective areas RA may be smaller or larger than that of the fourth display areas LEA4 in some embodiments. The size of the transmissive area TA may vary depending on the size of the reflective areas RA.

The light-emitting areas EA may be arranged in the fourth display areas LEA4. The variably transparent layer HTL may be located in the reflective areas RA. The transmissive area TA may be arranged around the reflective areas RA and the fourth display areas LEA4 (e.g., in a plan view), and the light-emitting areas EA and the variably transparent layer HTL are not arranged in the transmissive area TA.

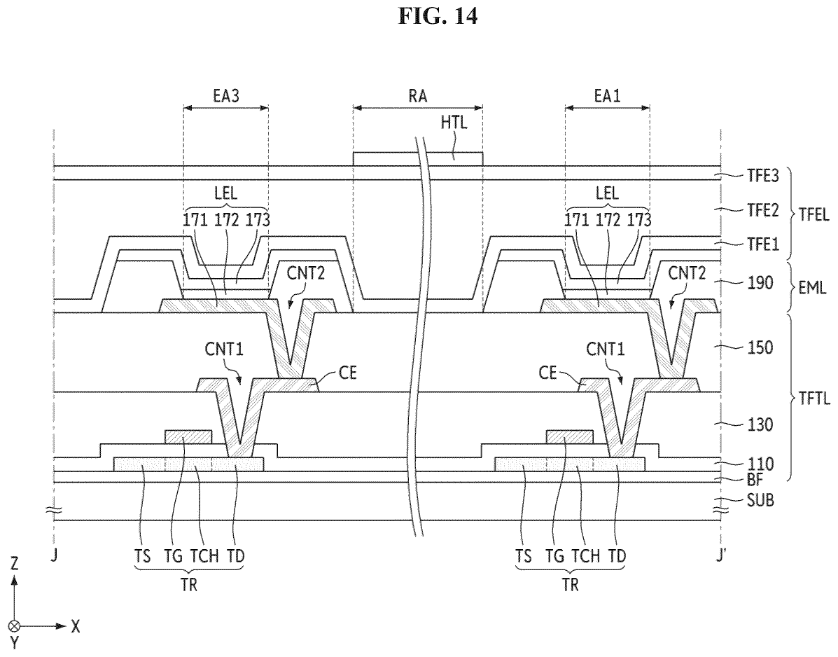

FIG. 14 is a cross-sectional view, taken along line J-J′ of FIG. 13. The following description will focus on differences and the redundant description will be omitted for economy of explanation.

Referring to FIG. 14, in an embodiment a display layer 10a may include a substrate SUB, a thin-film transistor layer TFTL, a light-emitting material layer EML, an encapsulation layer TFEL and a variably transparent layer HTL.

Compared to FIG. 12, while the variably transparent layer HTL is located to overlap the light-emitting areas EA and the pixel-defining layer 190 in the third direction (e.g., the z-axis direction) in FIG. 12, the variably transparent layer HTL of FIG. 14 may be arranged only in the reflective area RA.

Since the variably transparent layer HTL is arranged only in the reflective area RA, the light from the light-emitting areas EA may be output to the outside without passing through the variably transparent layer HTL. Accordingly, the light-emitting efficiency of the light-emitting areas EA can be increased.

In addition, since the variably transparent layer HTL is not arranged in the transmissive area TA, the light incident on the transmissive area TA may be transmitted to the outside without passing through the variably transparent layer HTL. Accordingly, the transmission efficiency of light transmitted in the transmissive area TA can be increased.

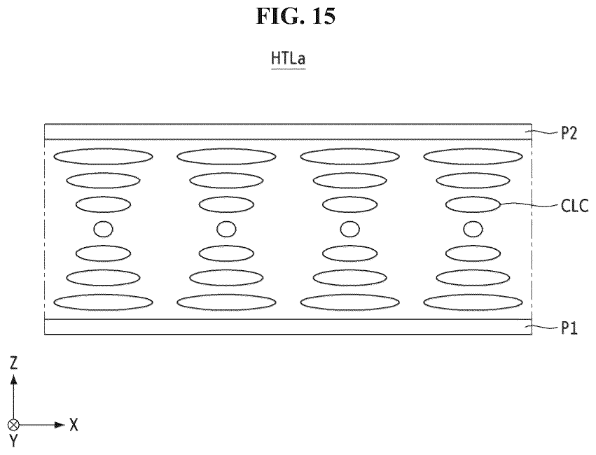

FIG. 15 is a cross-sectional view for illustrating an example of the variably transparent layer of FIG. 14.

Referring to FIG. 15, in an embodiment a variably transparent layer HTLa may include a first plate P1, a second plate P2, and a cholesteric liquid crystal CLC between the the first and second plates P1, P2 (e.g., in the z-axis direction).

In an embodiment, the first plate P1 and the second plate P2 may be made of an insulating material such as glass, quartz, and polymer resin. The first plate P1 and the second plate P2 may be made of a transparent material that allows light to pass through. The first plate P1 and the second plate P2 may be extended in the first direction (e.g., the x-axis direction).

The cholesteric liquid crystal CLC may be arranged between the first plate P1 and the second plate P2 (e.g., in the z-axis direction). In an embodiment, the cholesteric liquid crystal CLC may be liquid crystal molecules arranged in a helical structure, and the twist of the molecules may be repeated periodically. The cholesteric liquid crystal CLC may reflect light of different wavelengths depending on the degree of twist of the molecules (e.g., the pitch of the repeated twists of the molecules). The more cholesteric liquid crystal CLC is twisted per unit length (e.g., the shorter the pitch of the twists is), the cholesteric liquid crystal CLC may reflect light of shorter wavelengths.

In some embodiments, the variably transparent layer HTL may comprise an electrophoretic display.

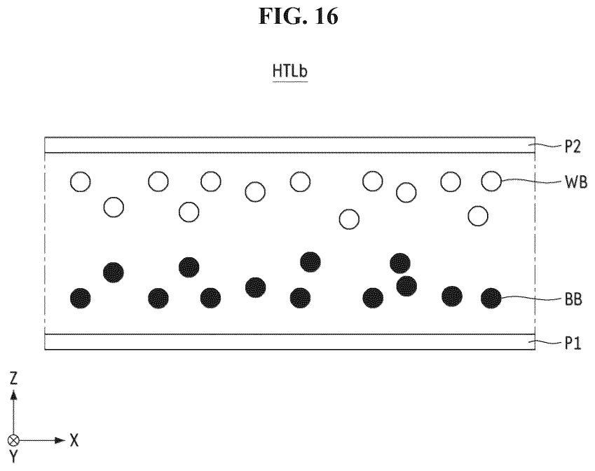

FIG. 16 is a cross-sectional view for illustrating another example of the variably transparent layer of FIG. 14. The following description will focus on differences and the redundant description will be omitted for economy of explanation.

Referring to FIG. 16, in an embodiment a variably transparent layer HTLb may include a first plate P1, a second plate P2, first color balls WB and second color balls BB disposed therebetween (e.g., in the z-axis direction).

The first plate P1 and the second plate P2 may include electrodes. The first color balls WB and the second color balls BB may move according to the voltage applied to the first plate P1 and the second plate P2.

For example, in an embodiment the first color balls WB may include white pigments. The first color balls WB may be positively charged. In contrast, the second color balls BB may include black pigments. The second color balls BB may be negatively charged. Accordingly, when the electrode of the first plate P1 is positive, the second color balls BB may be arranged towards the first plate P1, while the first color balls WB may be arranged toward the second plate P2. On the contrary, when the electrode of the first plate P1 is negative, the first color balls WB may be arranged toward the first plate P1, while the second color balls BB may be arranged towards the second plate P2.

When the first color balls WB are arranged towards the second plate P2 as shown in the drawing, the variably transparent layer HTLb may reflect light incident from the outside. On the contrary, when the second color balls BB are arranged towards the second plate P2, the variably transparent layer HTLb may absorb light incident from the outside. In this manner, the variably transparent layer HTLb may variably reflect external light in accordance with incident surfaces.

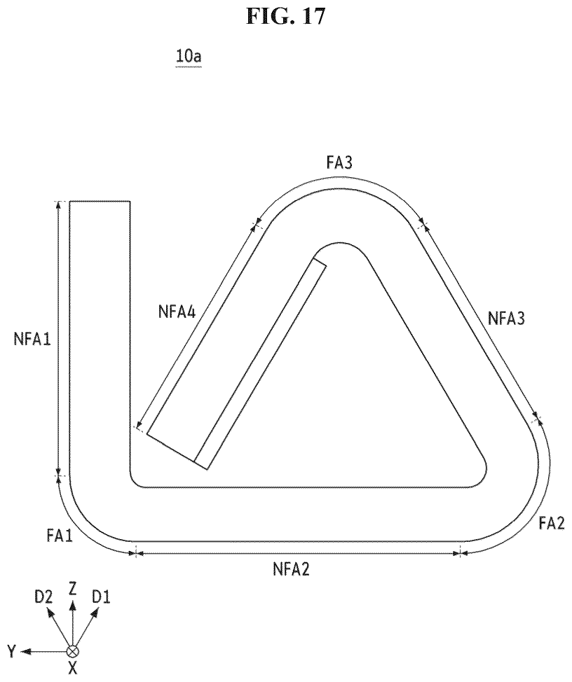

FIG. 17 is a side view showing another example of the folding mode of the display device of FIG. 1. The following description will focus on differences and the redundant description will be omitted for economy of explanation.

Referring to FIG. 17, in an embodiment the display device 10a may include a first non-folding display area NFA1, a second non-folding display area NFA2, a third non-folding display area NFA3, a fourth non-folding display area NFA4, a first folding display area FA1, a second folding display area FA2, and a third folding display area FA3.

Compared with FIG. 5, the third non-folding display area NFA3 of FIG. 17 may be arranged in a fifth direction D2 crossing the second direction (e.g., the y-axis direction) and the third direction (e.g., the z-axis direction). The fourth non-folding display area NFA4 may be arranged in a fourth direction D1 crossing the second direction (e.g. the y-axis direction) and the third direction (e.g., the z-axis direction).

In an embodiment, the length of the first non-folding display area NFA1 in the third direction (e.g., the z-axis direction) may be less than the length of the second non-folding display area NFA2 in the second direction (e.g., the y-axis direction). The length of the second non-folding display area NFA2 in the second direction (e.g., the y-axis direction) may be substantially equal to the length of the third non-folding display area NFA3 in the fifth direction D2. The length of the third non-folding display area NFA3 in the fifth direction D2 may be substantially equal to the length of the fourth non-folding display area NFA4 in the fourth direction D1.

Compared with FIG. 5, referring to FIG. 17, the angles formed by the second non-folding display area NFA2 to the fourth non-folding display area NFA4 may differ.

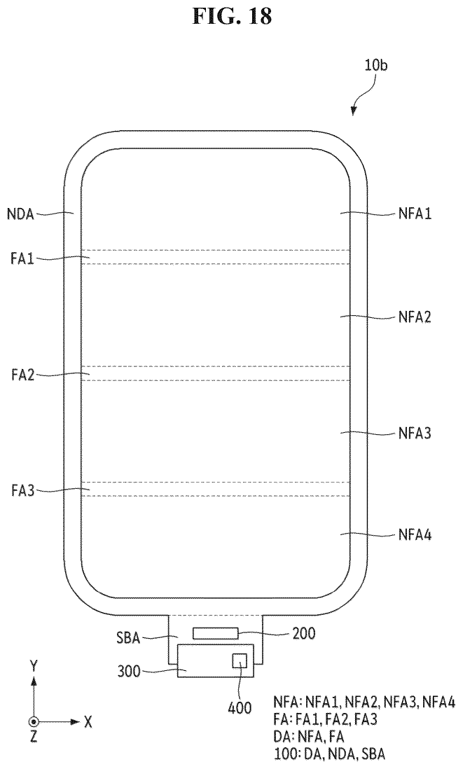

FIG. 18 is a front view for illustrating a display device according to some embodiments of the present disclosure. The following description will focus on differences and the redundant description will be omitted for economy of explanation.

Referring to FIG. 18, a display device 10b according to an embodiment of the present disclosure may include a display panel 100, a display driver circuit 200, a display circuit board 300 and a touch driver circuit 400.

Referring to FIG. 1, the display device 10b may further include the touch driver circuit 400. The touch driver circuit 400 may be located on the display circuit board 300. The touch driver circuit 400 may be implemented as an integrated circuit (IC) and may be attached on the display circuit board 300.

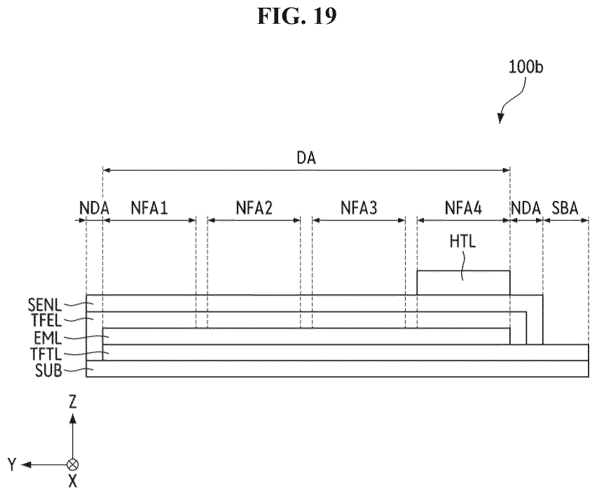

The touch driver circuit 400 may be electrically connected to the sensor electrodes of the touch sensing layer SENL (see FIG. 19) of the display panel 100. In an embodiment, the touch driver circuit 400 may apply driving signals to the sensor electrodes of the touch sensing layer SENL and may measure mutual capacitances of the sensor electrodes. The driving signals may have driving pulses. The touch driver circuit 400 can determine whether a user has touched or the presence of nearby object based on the mutual capacitances. A user's touch may refer to that an object such as the user's finger or a pen is brought into direct contact with a surface of the display device 10b arranged on the touch sensing layer SENL. The user's near proximity may refer to that an object such as the user's finger and a pen is hovering over a surface of the display device 10b without directly contacting the surface of the display device 10b.

FIG. 19 is a side view showing an example of the display panel of FIG. 18. The following description will focus on differences and the redundant description will be omitted for economy of explanation.

Referring to FIG. 19, in an embodiment a display layer 100b may include a substrate SUB, a thin-film transistor layer TFTL, a light-emitting material layer EML, an encapsulation layer TFEL, a touch sensing layer SENL, and a variably transparent layer HTL.

Compared with FIG. 2, the display panel 100b may further include the touch sensing layer SENL located between the encapsulation layer TFEL and the variably transparent layer HTL (e.g., in the z-axis direction).

The touch sensing layer SENL may be arranged in the display area DA and the non-display area NDA. The touch sensing layer SENL may sense a touch of a person or an object using sensor electrodes.

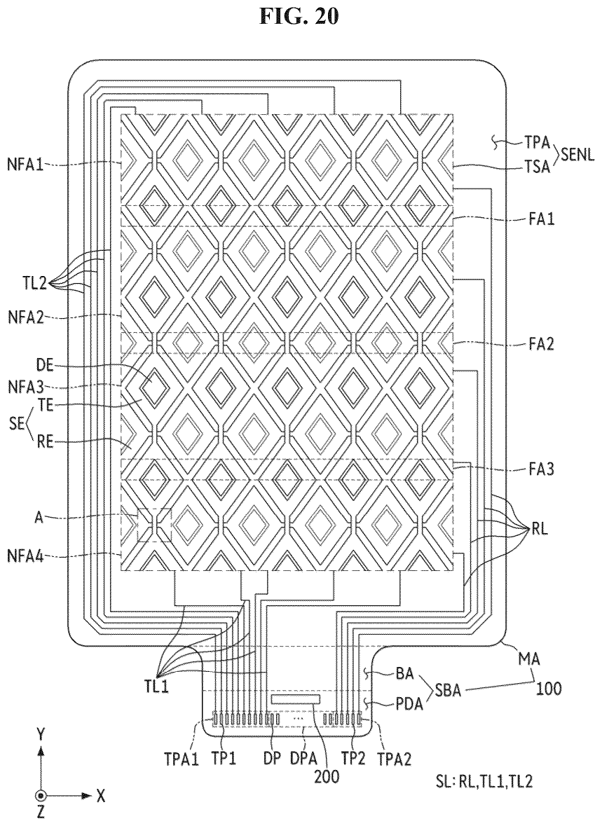

The touch sensing layer SENL will be described in detail with reference to FIG. 20.

FIG. 20 is a layout diagram for illustrating the touch sensing layer of FIG. 19.

In the example shown in FIG. 20, the sensor electrodes SE of the touch sensing layer SENL include two kinds of electrodes, e.g., the driving electrodes TE and the sensing electrodes RE, the mutual capacitive sensing is carried out, such as driving signals are applied to the driving electrodes TE and then the voltages charged at the mutual capacitances can be sensed through the sensing electrodes RE. It is, however, to be understood that embodiments of the present disclosure are not necessarily limited thereto. The driving electrodes TE and the sensor electrodes RE may be collectively referred to as “touch electrodes”.

For convenience of illustration, FIG. 20 shows only the driving electrodes TE, the sensing electrodes RE, dummy patterns DE, sensor lines TL1, TL2 and RL, and sensor pads TP1 and TP2.

Referring to FIG. 20, the touch sensing layer SENL may include a touch sensor area TSA for sensing a user's touch, and a touch peripheral area TPA located around the touch sensor area TSA (e.g., in a plan view). The touch sensor area TSA may overlap the display area DA of FIG. 18, and the touch peripheral area TPA may overlap the non-display area NDA of FIG. 18.

In an embodiment, the touch sensor area TSA may include the driving electrodes TE, the sensing electrodes RE and the dummy patterns DE. The driving electrodes TE and the sensing electrodes RE may be electrodes for forming mutual capacitance to sense a touch of an object or a person.

In an embodiment, the sensing electrodes RE may be arranged in the first direction (e.g., the x-axis direction) and second direction (e.g., the y-axis direction). The sensing electrodes RE may be electrically connected to one another in the first direction (e.g., the x-axis direction). The sensing electrodes RE may be connected to one another in the first direction (e.g., the x-axis direction). The sensing electrodes RE adjacent to one another in the second direction (e.g., the y-axis direction) may be electrically separated from one another.

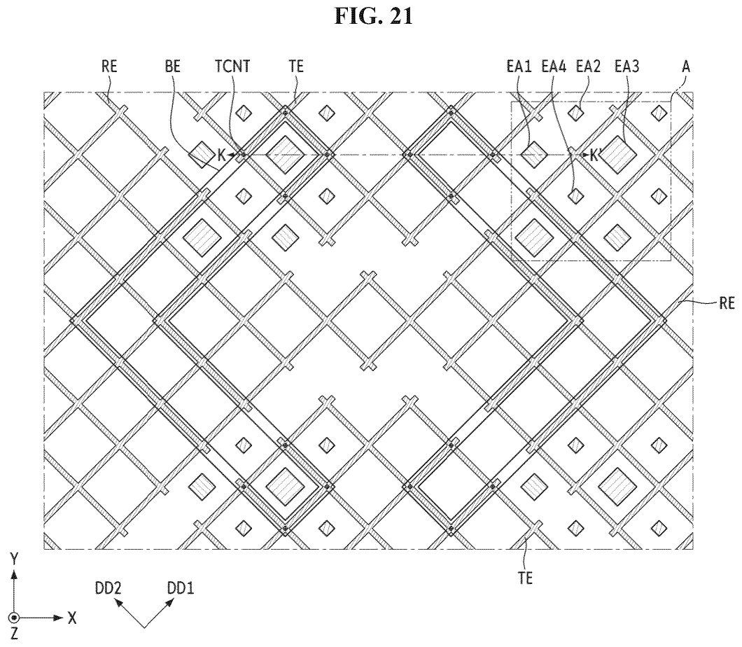

The driving electrodes TE may be arranged in the first direction (e.g., the x-axis direction) and second direction (e.g., the y-axis direction). The driving electrodes TE adjacent to one another in the first direction (e.g., the x-axis direction) may be electrically separated from one another. The driving electrodes TE may be electrically connected to one another in the second direction (e.g., the y-axis direction). For example, the driving electrodes TE adjacent to one another in the second direction (e.g., the y-axis direction) may be connected through bridge electrodes BE as shown in FIG. 21.

Each of the dummy patterns DE may be surrounded by the driving electrode TE or the sensing electrode RE. Each of the dummy patterns DE may be electrically separated from the driving electrode TE or the sensing electrode RE. Each of the dummy patterns DE may be spaced apart from the driving electrode TE or the sensing electrode RE. Each of the dummy patterns DE may be electrically floating.

In FIG. 20, the driving electrodes TE, the sensing electrodes RE and the dummy patterns DE each have a diamond shape when viewed from the top (e.g., in a plan view), but embodiments of the present disclosure are not necessarily limited thereto. For example, each of the driving electrodes TE, the sensing electrodes RE and the dummy patterns DE may have other quadrangular shape than a diamond, other polygonal shapes than a quadrangular shape, a circle or an ellipse when viewed from the top (e.g., in a plan view).

The sensor lines TL1, TL2 and RL may be arranged in a sensor peripheral area TPA. The sensor lines TL1, TL2 and RL include sensing lines RL connected to the sensing electrodes RE, and first driving lines TL1 and second driving lines TL2 connected to the driving electrodes TE.

The sensing electrodes RE arranged on one side of the touch sensor area TSA may be connected to the sensing lines RL, respectively. For example, in an embodiment some of the sensing electrodes RE electrically connected in the first direction (e.g., the x-axis direction) that are located at the right end may be connected to the sensing lines RL as shown in FIG. 20. The sensing lines RL may be connected to second sensor pads TP2, respectively. Thus, the touch driver circuit 400 may be electrically connected to the sensing electrodes RE.

In an embodiment, the driving electrodes TE arranged on one side (e.g., a lower side in the −y-axis direction) of the touch sensor area TSA may be connected to the first driving lines TL1, respectively, while the driving electrodes TE arranged on the other side (e.g., an upper side in the y-axis direction) of the touch sensor area TSA may be connected to the second driving lines TL2. For example, some of the driving electrodes TE electrically connected to one another in the second direction (e.g., the −y-axis direction) on the lowermost side may be connected to the first driving line TL1, while some of the driving electrodes TE arranged on the uppermost side (e.g., the y-axis direction) may be connected to the second driving line TL2, as shown in FIG. 20. The second driving lines TL2 may be connected to the driving electrodes TE on the upper side of the touch sensor area TSA via the left outer side of the touch sensor area TSA.

The first driving lines TL1 and the second driving lines TL2 may be connected to (e.g., directly connected thereto) the first sensor pads TP1, respectively. Thus, the touch driver circuit 400 may be electrically connected to the driving electrodes TE. The driving electrodes TE are connected to the driving lines TL1 and TL2 on both sides of the touch sensor area TSA, and receive the touch driving signals. Therefore, it is possible to prevent a difference between the touch driving signals applied to the driving electrodes TE arranged on the lower side of the touch sensor area TSA and the touch driving signals applied to the driving electrodes TE arranged on the upper side of the touch sensor area TSA which occurs due to the RC delay of the touch driving signals.

The first sensor pad area TPA1 in which the first sensor pads TP1 are arranged may be located on one side (e.g., a left side in the-x-axis direction) of the display pad area DP in which the display pads DPA are arranged. The second sensor pad area TPA2 in which the second sensor pads TP2 are arranged may be located on the opposite side (e.g., a right side in the x-axis direction) of the display pad area DPA. The display pads DP may be electrically connected to data lines of the display panel 100.

The display pad area DPA, the first sensor pad area TPA1 and the second sensor pad area TPA2 may correspond to the pads of the display panel 100 connected to the display circuit board 300 shown in FIG. 2. The display circuit board 300 may be located on the display pads DP, the first sensor pads TP1, and the second sensor pads TP2. In an embodiment, the display pads DP, the first sensor pads TP1 and the second sensor pads TP2 may be electrically connected to the display circuit board 300 using a low-resistance, high-reliability material such as an anisotropic conductive film or a SAP. Therefore, the display pads DP, the first sensor pads TP1 and the second sensor pads TP2 may be electrically connected to the touch driver circuit 400 located on the display circuit board 300.

FIG. 21 is an enlarged view of area A of FIG. 20.

Referring to FIG. 21, the driving electrodes TE and the sensing electrodes RE are formed in the same layer and thus they may be spaced apart from each other (e.g., in a plan view). For example, there may be a gap between adjacent ones of the driving electrodes TE and the sensing electrodes RE.

In addition, the dummy patterns DE may also be located in the same layer as the driving electrodes TE and the sensing electrodes RE. For example, there may be a gap between adjacent ones of the driving electrodes TE and the dummy patterns DE and between adjacent ones of the sensing electrodes RE and the dummy patterns DE.

In an embodiment, the bridge electrodes BE may be arranged in a different layer from the driving electrodes TE and the sensing electrodes RE. Each of the bridge electrodes BE may be bent at least once. For example, the bridge electrodes BE may have a bent orientation in which there is at least one bend in each of the bridge electrodes BE (e.g., in a plan view). Although the connection electrodes BE have the shape of angle brackets “<” or “>” in the example shown in FIG. 21, the shape of the connection electrodes BE when viewed from the top (e.g., in a plan view) is not necessarily limited thereto. Since the driving electrodes TE adjacent to each other in the second direction (e.g., the y-axis direction) are connected by the plurality of bridge electrodes BE, even if any of the bridge electrodes BE is disconnected, the driving electrodes TE can still be stably connected with each other in the second direction (e.g., the y-axis direction). Although two adjacent ones of the driving electrodes TE are connected by two bridge electrodes BE in the example shown in FIG. 21, the number of bridge electrodes BE is not necessarily limited to two.

The bridge electrodes BE may overlap with the driving electrodes TE adjacent to one another in the second direction (e.g., the y-axis direction) in the third direction (e.g., the z-axis direction), which is the thickness direction of the substrate SUB. The bridge electrodes BE may overlap with the sensing electrodes RE in the third direction (e.g., the z-axis direction). One side of each of the bridge electrodes BE may be connected to one of the driving electrodes TE adjacent to each other in the second direction (e.g., the y-axis direction) through touch contact holes TCNT. The other side of each of the bridge electrodes BE may be connected to another one of the driving electrodes TE adjacent to each other in the second direction (e.g., the y-axis direction) through touch contact holes TCNT. The bridge electrodes BE1 may also be referred to herein as “touch connection electrodes” herein.

The driving electrodes TE and the sensing electrodes RE may be electrically separated from each other at their intersections by virtue of the bridge electrodes BE. Accordingly, mutual capacitance can be formed between the driving electrodes TE and the sensing electrodes RE.

Each of the driving electrodes TE, the sensing electrodes RE and the bridge electrodes BE may have a mesh structure or a net structure when viewed from the top (e.g., in a plan view). In addition, each of the dummy patterns DE may have a shape of a mesh structure or a net structure when viewed from the top (e.g., in a plan view). Accordingly, the driving electrodes TE, the sensing electrodes RE, the bridge electrodes BE and the dummy patterns DE may be spaced apart from the light-emitting areas EA of each of the pixels. Therefore, it is possible to prevent the luminance of the lights output from the light-emitting areas EA from decreasing, which may occur as the lights are covered by the driving electrodes TE, the sensing electrodes RE, the bridge electrodes BE and the dummy patterns DE.

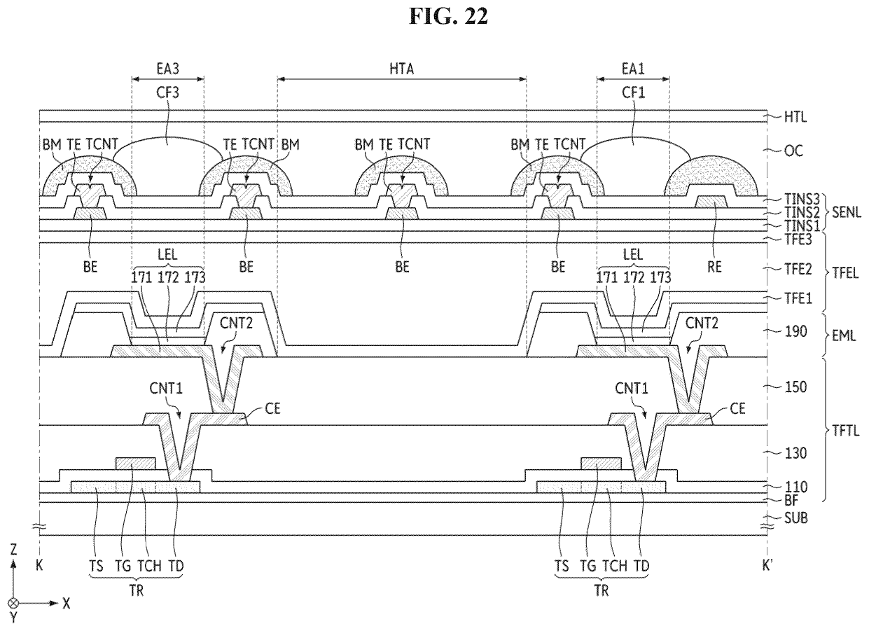

FIG. 22 is a cross-sectional view, taken along line K-K′ of FIG. 21. The following description will focus on differences and the redundant description will be omitted for economy of explanation.

Referring to FIG. 22, in an embodiment a display layer 100b may include a substrate SUB, a thin-film transistor layer TFTL, a light-emitting material layer EML, an encapsulation layer TFEL, a touch sensing layer SENL, and a variably transparent layer HTL.

Compared with FIG. 12, the display panel 100b may further include the touch sensing layer SENL located between the encapsulation layer TFEL and the variably transparent layer HTL.

In an embodiment, the touch sensing layer SENL may include a first touch insulating layer TINS1, a second touch insulating layer TINS2, third touch insulating layer TINS3, driving electrode TE, sensing electrode RE, and touch connection electrodes BE.

A first touch insulating layer TINS1 may be located on the encapsulation layer TFEL (e.g., disposed directly thereon in the z-axis direction). In an embodiment, the first touch insulating film TINS1 may be, but is not necessarily limited to, a silicon nitride layer, a silicon oxynitride layer, a silicon oxide layer, a titanium oxide layer, or an aluminum oxide layer.

The touch connection electrodes BE may be arranged on the first touch insulating layer TINS1 (e.g., disposed directly thereon in the z-axis direction). In an embodiment, the touch connection electrodes BE may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The second touch insulating layer TINS2 may be located on (e.g., disposed directly thereon) the touch connection electrodes BE. In an embodiment, the second touch insulating layer TINS2 may be implemented as an inorganic layer, for example, a silicon nitride layer, a silicon oxynitride layer, a silicon oxide layer, a titanium oxide layer, or an aluminum oxide layer.

The driving electrodes TE and the sensing electrodes RE may be arranged on the second touch insulating layer TINS2. In addition to the driving electrodes TE and the sensing electrodes RE, the dummy patterns DE, the first driving lines TL1, the second driving lines TL2 and the sensing lines RL shown in FIG. 20 may be arranged on the second touch insulating layer TINS2.

The driving electrodes TE and the sensing electrodes RE may overlap with the touch connection electrodes BE in the third direction (e.g., the z-axis direction). The driving electrodes TE may be connected to the touch connection electrodes BE through the touch contact holes TCNT penetrating through the second touch insulating layer TINS2.

The third touch insulating layer TINS3 may be formed on the driving electrodes TE and the sensing electrodes RE (e.g., disposed directly thereon in the third direction DR3). The third touch insulating layer TINS3 may provide a flat surface over the driving electrodes TE, the sensing electrodes RE and the touch connection electrodes BE having different heights. In an embodiment, the third touch insulating layer TINS3 may be implemented as an inorganic film, for example, a silicon nitride layer, a silicon oxynitride layer, a silicon oxide layer, a titanium oxide layer, or an aluminum oxide layer. The first to third touch insulating layers TINS1 to TINS3 may comprise a plurality of inorganic insulating layers. However, embodiments of the present disclosure are not necessarily limited thereto and the number of the plurality of inorganic insulating layers and the arrangement thereof may vary.

A color filter layer may be located on the touch sensing layer SENL. In an embodiment, the color filter layer may include color filters CF1, CF2 and CF3 and a black matrix BM.

The color filters CF1, CF2 and CF3 may include first color filters to third color filters CF1, CF2 and CF3.

The first color filter CF1 may overlap with the first light-emitting area EA1 in the third direction (e.g., the z-axis direction). The first color filter CF1 may transmit light of the first color output from the first light-emitting area EA1.

The second color filter CF2 may overlap with the second light-emitting area EA2 or the fourth light-emitting area EA4 in the third direction (e.g., the z-axis direction). The second color filter CF2 may transmit light of the second color output from the second light-emitting area EA2 or the fourth light-emitting area EA4.

The third color filter CF3 may overlap with the third light-emitting area EA3 in the third direction (e.g., the z-axis direction). The third color filter CF3 may transmit light of the third color output from the third light-emitting area EA3.

The black matrix BM may overlap with the driving electrodes TE, the sensing electrodes RE, and the touch connection electrodes BE. The black matrix BM may be formed using a material that absorbs visible light, e.g., a metal material, a resin material including a pigment or a dye, etc. The black matrix BM can prevent the driving electrodes TE, the sensing electrodes RE and the touch connection electrodes BE from being recognized.

As shown in FIG. 22, as the color filters CF1, CF2 and CF3 are arranged on the black matrix BM and may be formed after the black matrix BM has been formed on the touch sensing layer SENL.

An overcoat layer OC may be formed on (e.g., formed directly thereon) the color filter layer. The overcoat layer OC may provide a flat surface over the color filter layer having different heights. The overcoat layer OC may be made of a transparent material. For example, in an embodiment the overcoat layer OC may include, but is not necessarily limited to, a colorless light-transmitting organic material such as an acrylic resin.

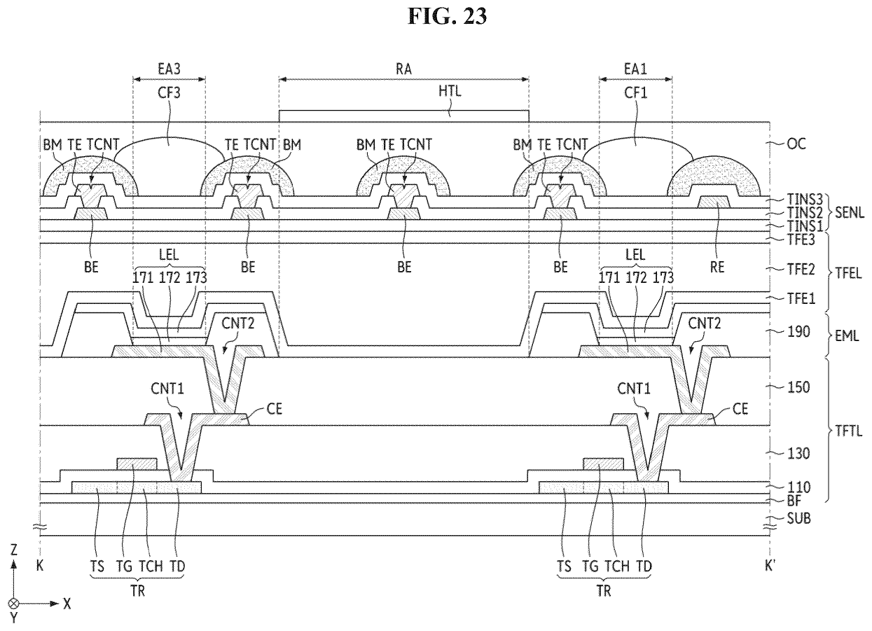

FIG. 23 is a cross-sectional view, taken along line K-K′ of FIG. 21. The following description will focus on differences and the redundant description will be omitted for economy of explanation.

Compared with FIG. 14, the display panel 100b may further include the touch sensing layer SENL located between the encapsulation layer TFEL and the variably transparent layer HTL (e.g., in the z-axis direction). The structure and function of the touch sensing layer SENL are substantially identical to those described above with reference to FIG. 22; and, therefore, the redundant descriptions will be omitted for economy of explanation.

Compared to FIG. 22, the variably transparent layer HTL of the display panel 100b may be placed only in the reflective area RA. Due to this arrangement of the variably transparent layer HTL, lights output from the light-emitting area EA exit to the outside without passing through the variably transparent layer HTL, so the light emission efficiency can be increased. In addition, since the lights that transmit the transmissive area TA do not pass through the variably transparent layer HTL, the transmission efficiency can be increased.

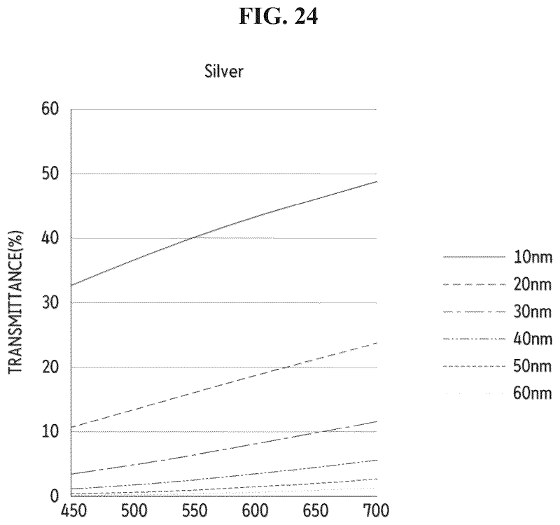

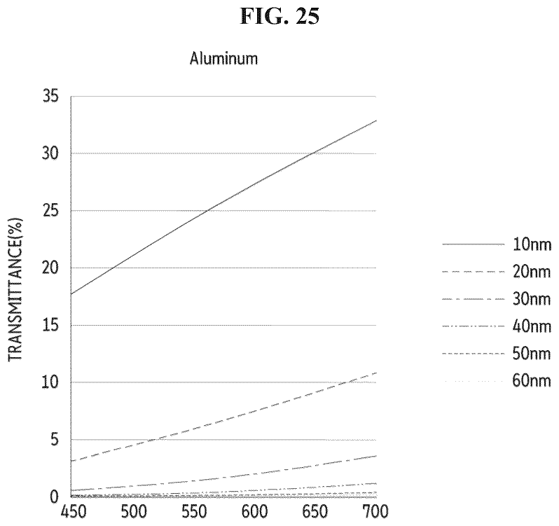

FIGS. 24 and 25 are views for illustrating the variably transparent layers of FIGS. 22 and 23.

FIG. 24 is a graph showing transmittance versus wavelength for different thicknesses of silver (Ag). FIG. 25 is a graph showing transmittance versus wavelength for different thicknesses of Aluminum (Al).

Referring to FIG. 24, silver (Ag) may have different transmittances depending on its thickness. For example, when the thickness of silver is 10 nm, it may have the transmittance of approximately 32% for light having the wavelength of 450 nm. When the thickness of silver is 10 nm, the transmittance may increase with the wavelength.

For another example, when the thickness of silver is 20 nm, it may have the transmittance of approximately 11% for light having the wavelength of 450 nm. When the thickness of silver is 20 nm, the transmittance may increase with the wavelength.

For another example, when the thickness of silver is 30 nm, it may have the transmittance of approximately 4% for light having the wavelength of 450 nm. When the thickness of silver is 30 nm, the transmittance may increase with the wavelength.

Referring to FIG. 25, aluminum (Al) may have different transmittances depending on its thickness. For example, when the thickness of aluminum is 10 nm, it may have the transmittance of approximately 18% for light having the wavelength of 450 nm. When the thickness of aluminum is 10 nm, the transmittance may increase with the wavelength.

For another example, when the thickness of aluminum is 20 nm, it may have the transmittance of approximately 4% for light having the wavelength of 450 nm. When the thickness of aluminum is 20 nm, the transmittance may increase with the wavelength.

For another example, when the thickness of aluminum is 30 nm, it may have the transmittance of approximately 1% for light having the wavelength of 450 nm. When the thickness of aluminum is 30 nm, the transmittance may increase with the wavelength.

As described above, it can be seen that the transmittance is increased as the metal is thinner and the wavelength is longer. By utilizing such characteristics of the metal, a metal layer of a thickness of 50 nm or less may be used as the variably transparent layer HTL.

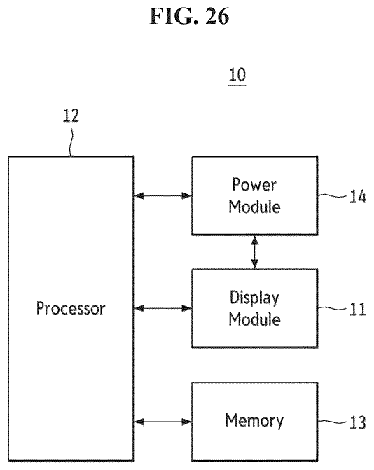

FIG. 26 is a block diagram for illustrating an electronic device including the display device according to some embodiments of the present disclosure.

Referring to FIG. 26, an electronic device 1 according to some embodiments of the present disclosure may include a display module 11, a processor 12, a memory 13, and a power module 14.

The processor 12 may include at least one of: a central processing unit (CPU), an application processor (AP), a graphic processing unit (GPU), a communication processor (CP), an image signal processor (ISP), and a controller.

The memory 15 may store data information required for the operation of the processor 12 or the display module 11. When the processor 12 executes an application stored in the memory 15, an image data signal and/or an input control signal may be transmitted to the display module 11. The display module 11 may process the received signal and output image information through a display screen.

The power module 14 may include a power supply module such as a power adapter and a battery device, and a power conversion module that converts the power supplied by the power supply module to generate power required for the operation of the electronic device 1.

At least one of the elements of the electronic device 1 described above may be included in the display devices according to embodiments described above. In addition, some of the individual modules functioning as a single module may be included in the display device while some others may be provided separately from the display device. For example, the display device may include the display module 11, and the processor 12, the memory 13 and the power module 14 may be implemented as other devices inside the electronic device 1 instead of the display device.

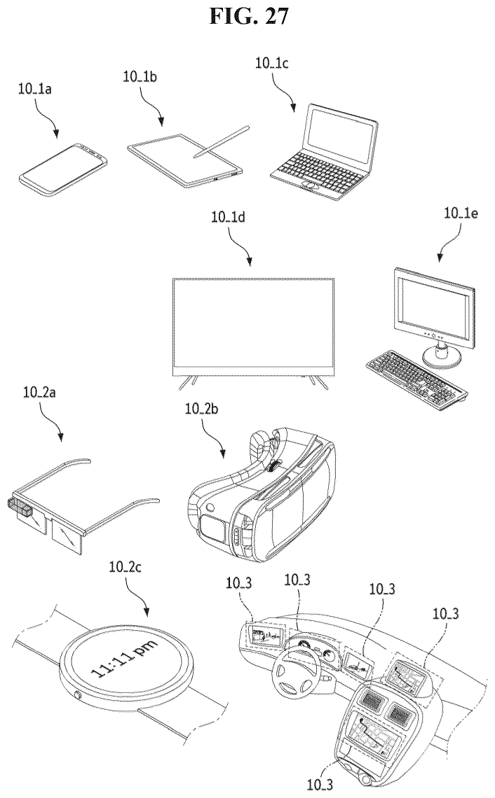

FIG. 27 is a view showing examples of electronic devices including the display device of FIG. 26.

Referring to FIG. 27, a variety of electronic devices employing display devices according to embodiments may include not only image display electronic devices such as a smart phone 10_1a, a tablet personal computer 10_1b, a laptop personal computer 10_1c, a television 10_1d and a desktop monitor 10_1e, but also wearable electronic devices including display modules such as smart glasses 10_2a, a head-mounted display 10_2b and a smart watch 10_2c, and electronic devices for vehicles 10_3 including display modules such as a center information display (CID) placed on the dashboard, the center fascia and the dashboard of a vehicle, and a room mirror display.

Although non-limiting embodiments of the present disclosure have been described with reference to the accompanying drawings, those skilled in the art would understand that various modifications and alterations may be made without departing from the technical idea or essential features of the present disclosure. Therefore, it should be understood that the above-mentioned embodiments are not limiting but illustrative in all aspects.

What is claimed is:

1. A display device comprising:
a first non-folding display area comprising a first display area;
a second non-folding display area comprising a second display area, the second non-folding display area is connected to a side of the first non-folding display area;
a third non-folding display area comprising a third display area, the third non-folding display area is connected to a side of the second non-folding display area;
a fourth non-folding display area comprising a fourth display area, the fourth non-folding display area is connected to a side of the third non-folding display area;
a first folding display area located between the first non-folding display area and the second non-folding display area, the first folding display area is bendable;
a second folding display area located between the second non-folding display area and the third non-folding display area, the second folding display area is bendable; and
a third folding display area located between the third non-folding display area and the fourth non-folding display area, the third folding display area is bendable,
wherein the display device operates in one of a first mode or a second mode, wherein the first non-folding display area to the fourth non-folding display area are arranged on a same plane as each other in the first mode and the first non-folding display area to the fourth non-folding display area are arranged on different planes from each other in the second mode, and
wherein the fourth non-folding display area comprises a variably transparent layer that reflects or transmits a portion of light incident from outside depending on incidence surfaces.

2. The display device of claim 1, wherein the fourth non-folding display area further comprises a variably transparent area located around the fourth display area, and
wherein the variably transparent layer is located in the variably transparent area.

3. The display device of claim 1, wherein the variably transparent layer comprises a metal layer having a thickness less than or equal to about 50 nm.

4. The display device of claim 1, wherein:
the fourth non-folding display area further comprises a reflective area located around the fourth display area, and a transmissive area located around the fourth display area and the reflective area; and
the variably transparent layer is located in the reflective area.

5. The display device of claim 4, wherein the variably transparent layer comprises cholesteric liquid crystal.

6. The display device of claim 4, wherein the variably transparent layer comprises an electrophoretic display.

7. The display device of claim 1, wherein the third non-folding display area further comprises a transparent area surrounding the third display area.

8. The display device of claim 1, wherein the variably transparent layer reflects light displayed in the second non-folding display area in the second mode.

9. The display device of claim 8, wherein the variably transparent layer transmits light displayed in the first non-folding display area in the second mode.

10. The display device of claim 9, wherein the third non-folding display area transmits light displayed in the fourth non-folding display area in the second mode.

11. The display device of claim 1, wherein:
light from the first display area is recognized as being adjacent to the second display area and the third display area in the second mode, and light from the fourth display area is recognized as being adjacent to the second display area and the third display area in the second mode.

12. The display device of claim 1, wherein the third non-folding display area and the fourth non-folding display area are transparent displays.

13. The display device of claim 1, further comprising:
a housing having the first to fourth non-folding display areas and the first to third folding display areas arranged therein, and
wherein the housing comprises:
a first non-folding housing portion located on a side of the first non-folding display area;
a second non-folding housing portion located on a side of the second non-folding display area;
a third non-folding housing portion located on some of edges of the third non-folding display area;
a fourth non-folding housing portion located on some of edges of the fourth non-folding display area;
a first folding housing portion located between the first non-folding housing portion and the second non-folding housing portion;
a second folding housing portion located between the second non-folding housing portion and the third non-folding housing portion; and
a third folding housing portion located between the third non-folding housing portion and the fourth non-folding housing portion.

14. The display device of claim 1, further comprising:
a housing having the first to fourth non-folding display areas and the first to third folding display areas arranged therein,
wherein the housing comprises:
a first non-folding housing portion located on some of edges of the first non-folding display area;
a second non-folding housing portion located on a surface of the second non-folding display area;
a third non-folding housing portion located on some of edges of the third non-folding display area;
a fourth non-folding housing portion located on some of edges of the fourth non-folding display area;
a first folding housing portion located between the first non-folding housing portion and the second non-folding housing portion;
a second folding housing portion located between the second non-folding housing portion and the third non-folding housing portion; and
a third folding housing portion located between the third non-folding housing portion and the fourth non-folding housing portion.

15. The display device of claim 1, wherein the display device includes a display panel, the display panel comprises:
a substrate;
a plurality of light-emitting elements arranged on the substrate, the plurality of light-emitting elements is arranged in light-emitting areas of the first non-folding display area to the fourth non-folding display area and the first folding display area to the third folding display area; and
an encapsulation layer located on the plurality of light-emitting elements.

16. The display device of claim 15, wherein the display panel further comprises: a plurality of inorganic insulating layers arranged on the encapsulation layer; and touch electrodes arranged between the plurality of inorganic insulating layers and forming a mutual capacitance with each other.

17. The display device of claim 16, wherein the display panel further comprises:
a black matrix overlapping with the touch electrodes in a thickness direction of the substrate; and
color filters overlapping with the light-emitting areas.

18. An electronic device comprising a display device,
wherein the display device comprises:
a first non-folding display area comprising a first display area;
a second non-folding display area comprising a second display area, the second non-folding display area is connected to a side of the first non-folding display area;
a third non-folding display area comprising a third display area, the third non-folding display area is connected to a side of the second non-folding display area;
a fourth non-folding display area comprising a fourth display area, the fourth non-folding display area is connected to a side of the third non-folding display area;
a first folding display area located between the first non-folding display area and the second non-folding display area, the first folding display area is bendable;
a second folding display area located between the second non-folding display area and the third non-folding display area, the second folding display area is bendable; and
a third folding display area located between the third non-folding display area and the fourth non-folding display area, the third folding display area is bendable,
wherein the display device operates in one of a first mode or a second mode, wherein the first non-folding display area to the fourth non-folding display area are arranged on a same plane as each other in the first mode and the first non-folding display area to the fourth non-folding display area are arranged on different planes from each other in the second mode, and
wherein the fourth non-folding display area comprises a variably transparent layer that reflects or transmits a portion of light incident from outside depending on incidence surfaces.

19. The electronic device of claim 18, wherein the fourth non-folding display area further comprises a variably transparent area located around the fourth display area, and wherein the variably transparent layer is located in the variably transparent area.

20. The electronic device of claim 18, wherein the fourth non-folding display area further comprises a reflective area located around the fourth display area, and a transmissive area located around the fourth display area and the reflective area, and wherein the variably transparent layer is located in the reflective area.
